(19) United States
(12) Patent Application Publication
(10) Pub. No.: US 2025/0017066 A1
(43) Pub. Date: Jan. 9, 2025

(54) DISPLAY DEVICE

(71) Applicant: Samsung Display Co., LTD., Yongin-si (KR)

(72) Inventors: Won Jun LEE, Yongin-si (KR); Dong Woo KIM, Yongin-si (KR); Se Hyun LEE, Yongin-si (KR)

(21) Appl. No.: 18/657,660

(22) Filed: May 7, 2024

(30) Foreign Application Priority Data
Jul. 4, 2023 (KR) 10-2023-0086477

(51) Int. Cl. H10K 59/32; H10K 59/38

(52) U.S. Cl. CPC H10K 59/32; H10K 59/38

(57) ABSTRACT

The present disclosure relates to a display device, and more particularly, to a display device capable of expanding the range of data voltages. According to an embodiment of the present disclosure, a display device includes: a substrate; a first electrode on the substrate; a second electrode on the first electrode; and a first middle layer between the first electrode and the second electrode in a first emission region, wherein the first middle layer includes a plurality of sub-middle layers in the first emission region, and the sub-middle layers of the first middle layer have different thicknesses.

### CROSS-REFERENCE TO RELATED APPLICATION

The present application claims priority to and the benefit of Korean Patent Application No. 10-2023-0086477, filed on Jul. 4, 2023, in the Korean Intellectual Property Office, the entire disclosure of which is incorporated by reference herein.

### BACKGROUND

### 1. Field

The present disclosure relates to a display device, and more particularly, to a display device capable of expanding the range of data voltages.

### 2. Description of the Related Art

An organic light-emitting display device includes display elements that exhibit variable luminance based on an electric current, such as, for example, organic light-emitting diodes (OLEDs).

### SUMMARY

Aspects and features of embodiments of the present disclosure provide a display device capable of expanding the range of data voltages.

The aspects and features of embodiments of the present disclosure are not limited to those mentioned above and additional aspects and features of the present disclosure, which are not mentioned herein, will be clearly understood by those skilled in the art from the following description of the present disclosure.

However, aspects and features of embodiments of the present disclosure are not restricted to those set forth herein. The above and other aspects and features of the present disclosure will become more apparent to one of ordinary skill in the art to which the present disclosure pertains by referencing the detailed description of the present disclosure given below.

According to one or more embodiments of the present disclosure, a display device including: a substrate; a first electrode on the substrate; a second electrode on the first electrode; and a first middle layer between the first electrode and the second electrode in a first emission region, wherein the first middle layer includes a plurality of sub-middle layers in the first emission region, and the sub-middle layers of the first middle layer have different thicknesses.

In one or more embodiments, the sub-middle layers of the first middle layer include different numbers of light-emitting layers.

In one or more embodiments, thicknesses of the sub-middle layers of the first middle layer are distances from a bottom surface of the first middle layer to top surfaces of uppermost light-emitting layers of the sub-middle layers of the first middle layer.

In one or more embodiments, the bottom surface of the first middle layer is an interface between the first electrode and the first middle layer.

In one or more embodiments, the uppermost light-emitting layers of the sub-middle layers of the first middle layer are most distant light-emitting layers of the sub-middle layers of the first middle layer from the first electrode.

In one or more embodiments, the top surfaces of the uppermost light-emitting layers of the sub-middle layers of the first middle layer are interfaces between the uppermost light-emitting layers of the sub-middle layers of the first middle layer and uppermost electron transport layers of the sub-middle layers of the first middle layer.

In one or more embodiments, the sub-middle layers of the first middle layer include different numbers of light-emitting units.

In one or more embodiments, each of the sub-middle layers of the first middle layer further includes a charge generation layer located between neighboring light-emitting units.

In one or more embodiments, the first middle layer further includes a functional layer in each of the light-emitting units.

In one or more embodiments, further including: a third electrode between the substrate and the second electrode; and a second middle layer between the second electrode and the third electrode in a second emission region, wherein the second middle layer includes a plurality of sub-middle layers located in the second emission region, and the sub-middle layers of the second middle layer have different thicknesses.

In one or more embodiments, the sub-middle layers of the second middle layer have a same thickness as their corresponding sub-middle layers of the first middle layer.

In one or more embodiments, the sub-middle layers of the second middle layer include a same number of light-emitting layers as their corresponding sub-middle layers of the first middle layer.

In one or more embodiments, the sub-middle layers of the second middle layer have a different thickness from their corresponding sub-middle layers of the first middle layer.

In one or more embodiments, the sub-middle layers of the second middle layer include a different number of light-emitting layers from their corresponding sub-middle layers of the first middle layer.

In one or more embodiments, the second electrode includes a plurality of sub-electrodes on the sub-middle layers of the first middle layer.

In one or more embodiments, the sub-electrodes are separate from one another.

In one or more embodiments, the first emission region includes a plurality of sub-emission regions corresponding to the sub-middle layers of the first middle layer.

In one or more embodiments, further including: a color filter on the second electrode in the first emission region.

In one or more embodiments, the sub-middle layers of the first middle layer include light-emitting layers configured to emit a same color of light.

In one or more embodiments, the sub-middle layers of the first middle layer include light-emitting layers configured to emit different colors of light.

In one or more embodiments, the sub-middle layers of the first middle layer are arranged in one direction.

In one or more embodiments, the sub-middle layers of the first middle layer include a first sub-middle layer and a second sub-middle layer having a greater thickness than the first sub-middle layer and surrounding the first sub-middle layer.

According to one or more embodiments of the present disclosure, a display device including: a substrate; a first electrode on the substrate; a second electrode on the first electrode; and a middle layer between the first electrode and the second electrode in an emission region, wherein the middle layer includes a plurality of sub-middle layers in the emission region, and at least two of the sub-middle layers include different numbers of light-emitting layers.

In one or more embodiments, the at least two of the sub-middle layers have different thicknesses.

According to the aforementioned and other embodiments of the present disclosure, the middle layer of each pixel includes a plurality of sub-middle layers and the sub-middle layers include different numbers of light-emitting layers. Consequently, a broader range of gray levels can be presented in each pixel even at lower voltages. As a result, the range of data voltages for generating a pixel voltage can be expanded.

It should be noted that the effects, aspects, and features, of the present disclosure are not limited to those described above, and other effects, aspects, and features of the present disclosure will be apparent from the following description.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of a display device according to one or more embodiments of the present disclosure;

FIG. 2 is a block diagram of the display device of FIG. 1;

FIG. 3 is an equivalent circuit diagram of a pixel of the display device of FIG. 1;

FIG. 4 is a plan view of multiple pixels of the display device of FIG. 1;

FIG. 5 is a cross-sectional view taken along the line I-I′ of FIG. 4;

FIG. 6 is a detailed cross-sectional view of a first light-emitting element of the display device of FIG. 5;

FIG. 7 is a detailed cross-sectional view of a first light-emitting element of the display device of FIG. 5;

FIG. 8 is a detailed cross-sectional view of a first light-emitting element of the display device of FIG. 5;

FIG. 9 is a detailed cross-sectional view of a first light-emitting element of the display device of FIG. 5;

FIG. 10 is a detailed cross-sectional view of a second light-emitting element of the display device of FIG. 5;

FIG. 11 is a detailed cross-sectional view of a third light-emitting element of the display device of FIG. 5;

FIG. 12 is a cross-sectional view, taken along the line I-I′ of FIG. 4, of a display device according to one or more embodiments of the present disclosure;

FIG. 13 is a cross-sectional view, taken along the line I-I′ of FIG. 4, of a display device according to one or more embodiments of the present disclosure;

FIG. 14 is a cross-sectional view of a first light-emitting element of the display device of FIG. 13;

FIG. 15 is a detailed cross-sectional view of a second light-emitting element of the display device of FIG. 13;

FIG. 16 is a detailed cross-sectional view of a third light-emitting element of the display device of FIG. 13;

FIG. 17 is a plan view of multiple pixels of a display device according to one or more embodiments of the present disclosure;

FIG. 18 is a plan view of multiple pixels of a display device according to one or more embodiments of the present disclosure;

FIG. 19 is a plan view of multiple pixels of a display device according to one or more embodiments of the present disclosure;

FIG. 20 is a plan view of multiple pixels of a display device according to one or more embodiments of the present disclosure;

FIG. 21 is a plan view of multiple pixels of a display device according to one or more embodiments of the present disclosure;

FIG. 22 is a plan view of multiple pixels of a display device according to one or more embodiments of the present disclosure;

FIG. 23 is a plan view of multiple pixels of a display device according to one or more embodiments of the present disclosure;

FIG. 24 is a cross-sectional view taken along the line II-II′ of FIG. 23;

FIG. 25 is a cross-sectional view of a first light-emitting element of a display device according to one or more embodiments of the present disclosure;

FIG. 26 is a table comparing the luminances at specific pixel voltages between a display device according to an embodiment of the present disclosure and a comparative example display device;

FIG. 27 is a graph illustrating the variations in light transmittance versus driving voltage for different tandem structures; and

FIG. 28 is a graph comparing the driving current error rates of a display device according to an embodiment of the present disclosure and a comparative example display device.

### DETAILED DESCRIPTION

The aspects, features, and methods of achieving them in the present disclosure will become apparent when referring to the detailed embodiments provided with the accompanying drawings. However, the present disclosure is not limited to the embodiments disclosed herein but can be implemented in various other forms. The embodiments are merely to ensure the completeness of the present disclosure to those skilled in the art and to fully convey the scope of the present disclosure as defined by the claims.

The term “on” referring to a component or layer being placed on another component or layer includes cases where another layer or component is present directly above or in between. Throughout the specification, the same reference numerals denote the same components. The shapes, sizes, ratios, angles, quantities, and the like disclosed in the drawings for illustrating the embodiments are examples and not limiting to the aspects described in the present disclosure.

Although terms such as “first,” “second,” and the like are used to describe various components, these terms are used for the purpose of distinguishing one component from another, and the components referred to by these terms are not limited by the corresponding terms. Therefore, the first component mentioned below may also be the second component within the technical concept of the present disclosure.

The characteristics of various embodiments of the present disclosure can be combined in part or in whole, or integrated in a technically diverse manner. Embodiments of the present disclosure may be implemented independently or all together in an associated relationship.

Embodiments of the present disclosure will hereinafter be described with reference to the accompanying drawings.

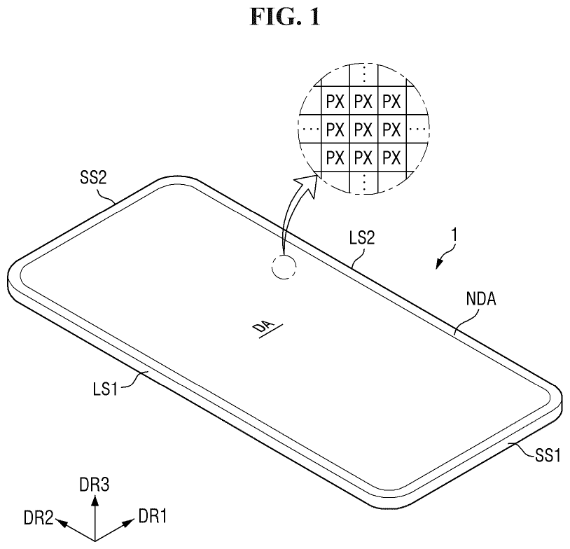

FIG. 1 is a perspective view of a display device according to one or more embodiments of the present disclosure.

First, second, and third directions DR1, DR2, and DR3 are defined in FIG. 1. Referring to FIG. 1, the first and second directions DR1 and DR2 may be mutually orthogonal, the first and third directions DR1 and DR3 may be mutually orthogonal, and the second and third direction DR2 and DR3 may be mutually orthogonal. The first direction DR1 may be a horizontal direction, the second direction DR2 may be a vertical direction, and the third direction DR3 may be a top-to-bottom direction or a thickness direction. In the following specification, unless specifically stated otherwise, the term “direction” may refer to both sides extending in the corresponding direction. Furthermore, if there is a need to distinguish between both sides extending in each direction, one of the sides will be referred to as “one side” or “first side,” and the other side as the “other side” or “second side.” With reference to FIG. 1, the direction indicated by each arrow is referred to as “one side” or “first side” in the corresponding direction, and the opposite direction is referred to as “the other side” or “second side” in the corresponding direction. However, it should be understood that the directions mentioned herein are referring to relative directions, and the present disclosure is not limited thereto.

For convenience, when referring to the surfaces of the display device 1 or the surfaces of each component of the display device 1, one surface facing the direction where an image is displayed, namely, one side in the third direction DR3, will hereinafter be referred to as the top surface, and the opposite surface will hereinafter be referred to as the bottom surface. However, the present disclosure is not limited to this. Alternatively, the one surface and the other surface can also be referred to as the front and back surfaces, respectively, or as the first and second surfaces, respectively. Also, when describing the relative position of each component of the display device 1, one side in the third direction DR3 can be referred to as the upper side, and the other side in the third direction DR3 can be referred to as the lower side.

The display device 1 may refer to any electronic device that provides a display screen. For example, mobile phones, smartphones, tablet personal computers (PCs), electronic watches, smartwatches, watch phones, mobile communication terminals, electronic notepads, e-book readers, portable multimedia players (PMPs), navigations, gaming consoles, digital cameras, televisions, laptops, netbooks, monitors, advertising boards, and/or Internet of Things (IoT) devices can be included in the display device 1. The embodiment of FIG. 1 illustrates an example where the display device 1 is applied to a medium-sized portable device such as a tablet PC.

There are no limitations to the planar shape of the display device 1. The planar shape of the display device 1 can be modified in various manners, such as into a rectangular shape, a square shape, a diamond shape, an another polygonal shape, a circular shape, an elliptical shape, etc., depending on the applicable field of the display device 1. The illustrated planar shape of the display device 1 is a rectangular shape with rounded corners, where the two long sides are positioned parallel to the second direction DR2. For convenience, one of the two opposing long sides of the rectangular shape, positioned on one side (i.e., on the left side in FIG. 1) in the first direction DR1 will hereinafter be referred to as a first long side LS1, and the long side on the other side (i.e., on the right side in FIG. 1) in the first direction DR1 will hereinafter be referred to as a second long side LS2. Similarly, one of the two opposing short sides of the rectangular shape, located on one side (i.e., on the bottom side in FIG. 1) in the second direction DR2 will hereinafter be referred to as a first short side SS1, and the short side located on the other side (i.e., on the top side in FIG. 1) in the second direction DR2 will hereinafter be referred to as a second short side SS2. The terms “first long side LS1,” “second long side LS2,” “first short side SS1,” and “second short side SS2” can also be used interchangeably to refer to their corresponding sides not only in the display device 1 but also in each component of the display device 1 that has a similar shape and positional relationship to the display device 1.

The display device 1 may include a display area DA and a non-display area NDA along an edge or periphery of the display area DA. The display area DA is an area where an image is displayed, and the non-display area NDA is an area where no image is displayed. The terms “display area DA” and “non-display area NDA” can also be used interchangeably to refer to their corresponding areas not only in the display device 1 but also in each component of the display device 1 that has a similar shape and positional relationship to the display device 1.

A plurality of pixels PX may be disposed in the display area DA. The structure of the pixels PX will be described later.

The non-display area NDA may be disposed around the display area DA. When the display area DA has a rectangular shape, the non-display area NDA may be positioned to be around (e.g., to surround) the four sides of the display area DA, but the present disclosure is not limited thereto. Alternatively, the non-display area NDA may be positioned on the outside of only some of the sides of the display area DA. Alternatively, the non-display area NDA may be positioned within the display area DA or may be surrounded by the display area DA.

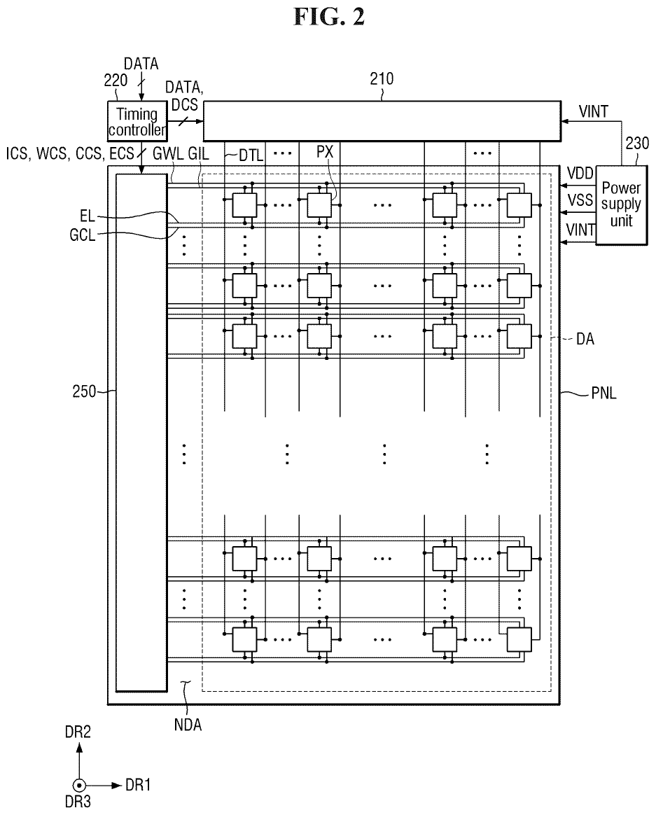

FIG. 2 is a block diagram of the display device of FIG. 1.

Referring to FIGS. 1 and 2, the display device 1 includes a display panel PNL. The display device 1 may further include a driving unit, which is connected to the display panel PNL.

In the present disclosure, the term “connection” not only means one component being physically connected to another component through direct contact, but also can refer to being connected through another component. Furthermore, the term “connection” can be understood as different parts being interconnected by virtue of being unified into a single component. Moreover, the connection between one component and another component can be interpreted to include not only direct physical contact, but also electrical connections through other components.

The display panel PNL provides a display screen. The direction in which the display panel PNL provides a display screen is the third direction DR3. The display panel PNL may have a similar planar shape to the display device 1. The display area DA of the display device 1 may also be referred to as the display area DA of the display panel PNL. The display area DA of the display panel PNL may include a plurality of pixels PX that are arranged in a matrix. In other words, the plurality of pixels PX may be arranged along rows and columns of a matrix.

Examples of the display panel PNL include an organic light-emitting display panel, a micro-light-emitting-diode (LED) display panel, a nano-LED display panel, a quantum-dot light-emitting display panel, a liquid crystal display (LCD) panel, a plasma display panel (PDP), a field emission display (FED) panel, an electrophoretic display panel, an electrowetting display panel, and/or the like. The display panel PNL will hereinafter be described as being, for example, an organic light-emitting display panel, but the present disclosure is not limited thereto. That is, the display panel PNL may also be applicable to other display panels within the scope of the present disclosure.

The driving unit drives the operation of the display panel PNL. At least some components of the driving unit drive the pixels PX in the display area DA of the display panel PNL. In one or more embodiments, the driving unit may be provided in the form of a chip, a film, and/or a circuit board.

The driving unit may include a display scan driver 250, a data driver 210, a timing controller 220, and a power supply 230. The driving unit may be positioned in the non-display area NDA of the display panel PNL, but some of the components of the driving unit may be disposed in the display area DA.

In the display area DA, not only the pixels PX, but also a plurality of lines connected to the driving unit may be disposed. The lines may include a plurality of display write lines GWL, a plurality of display initialization lines GIL, a plurality of display control lines GCL, a plurality of emission lines EL, and a plurality of data lines DTL.

The data lines DTL may extend in the second direction DR2. The display write lines GWL, the display initialization lines GIL, the display control lines GCL, and the emission lines EL may extend in the first direction DR1.

Each of the pixels PX may be connected to one of the display write lines GWL, one of the display initialization lines GIL, one of the display control lines GCL, and one of the emission lines EL. The pixels PX may receive data voltages from their corresponding data lines DTL, according to display write signals, display initialization signals, display control signals, and emission signals from their corresponding display write lines GWL, display initialization lines GIL, display control lines GCL, and emission lines EL. Subsequently, the pixels PX may emit light by applying driving currents to their light-emitting elements in accordance with the received data voltages.

The display scan driver 250 may be connected to the display write lines GWL, the display initialization lines GIL, the display control lines GCL, and the emission lines EL. The display scan driver 250 may include a display signal output module, which outputs the display write signals to be applied to the display write lines GWL, the display initialization signals to be applied to the display initialization lines GIL, and the display control signals to be applied to the display control lines GCL, and an emission signal output module, which outputs the emission signals to be applied to the emission lines EL.

The display scan driver 250 may receive a write control signal WCS, an initialization control signal ICS, a scan control signal CCS, and an emission control signal ECS from the timing controller 220. The display signal output module of the display scan driver 250 may generate the display write signals according to the write control signal WCS and may output the generated display write signals to the display write lines GWL. Also, the display signal output module of the display scan driver 250 may generate the display initialization signals according to the initialization control signal ICS and may output the generated display initialization signals to the display initialization lines GIL. Also, the display signal output module of the display scan driver 250 may generate the display control signals according to the scan control signal CCS and may output the generated display control signals to the display control lines GCL. Also, the display signal output module of the display scan driver 250 may generate the emission signals according to the emission control signal ECS and may output the generated emission signals to the emission lines EL.

The data driver 210 converts digital video data DATA into the data voltages and outputs the data voltages to the data lines DTL. The data driver 210 may output the data voltages in synchronization with the display write signals. The pixels PX may be selected by the display write signals from the display scan driver 250, and the data voltages may be supplied to the selected pixels PX.

The timing controller 220 receives the digital video data DATA and timing signals from an external graphics device. For example, the external graphics device may be a graphics card of a computer or a set-top box, but the present disclosure is not limited thereto.

The timing controller 220 may generate the write control signal WCS, the initialization control signal ICS, the scan control signal CCS, and the emission control signal ECS, which are for controlling the operational timings of the display scan driver 250, according to the timing signals. Also, the timing controller 220 may generate the data control signal DCS, which is for controlling the operational timings of the display scan driver 250, according to the timing signals.

The timing controller 220 may output the write control signal WCS, the initialization control signal ICS, the scan control signal CCS, and the emission control signal ECS to the display scan driver 250. The timing controller 220 may output the digital video data DATA and the data control signal DCS to the data driver 210.

The power supply 230 may generate a plurality of driving voltages and may output the driving voltages to the display area DA. The power supply 230 may output a first driving voltage VDD, a second driving voltage VSS, and an initialization voltage VINT to the display panel PNL. The first driving voltage VDD may be a high-potential driving voltage, the second driving voltage VSS may be a low-potential driving voltage, and the initialization voltage VINT may be a voltage for initializing the gate electrodes of driving transistors of the pixels PX.

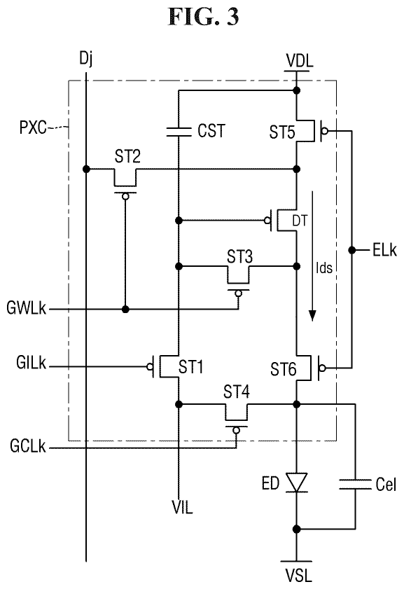

FIG. 3 is an equivalent circuit diagram of a pixel of the display device of FIG. 1.

Referring to FIG. 3, a pixel PX may be connected to a k-th display initialization line GILk, a k-th display write line GWLk, and a k-th display control line GCLk (where k is a positive integer). The pixel PX may also be connected to a first driving voltage line VDL, to which a first driving voltage is supplied, a second driving voltage line VSL, to which a second driving voltage is supplied, and an initialization voltage line VIL, to which an initialization voltage is supplied.

The pixel PX may include a pixel circuit PXC and a light-emitting element ED. The light-emitting element ED may be connected to the pixel circuit PXC.

The pixel circuit PXC may include a driving transistor DT, switching elements, and a capacitor CST. The switching elements may include first through sixth transistors ST1 through ST6.

The driving transistor DT may include a gate electrode, a first electrode, and a second electrode. The driving transistor DT controls a drain-source current (hereinafter, the driving current Ids), which flows between the first and second electrodes in accordance with a data voltage applied to the gate electrode. The driving current Ids, which flows through the channel of the driving transistor DT, is proportional to the square of the difference between the threshold voltage of the driving transistor DT and a voltage Vgs, which is the voltage applied between the first electrode and the gate electrode of the driving transistor DT, as indicated by Equation (1):

$$Ids = {k}^{′} * {( Vgs - Vth )}^{2} \qquad ( 1 )$$

where k′ denotes a proportionality coefficient determined by the structure and physical characteristics of the driving transistor DT, Vgs denotes the voltage between the first electrode and the gate electrode of the driving transistor DT, and Vth refers to the threshold voltage of the driving transistor DT.

The light-emitting element ED emits light in accordance with the driving current Ids. The greater the driving current Ids, the greater the amount of light emitted by the light-emitting element ED.

The light-emitting element ED may be an OLED including an organic light-emitting layer disposed between the anode and the cathode. Alternatively, the light-emitting element ED may be an inorganic light-emitting element including an inorganic semiconductor disposed between the anode and the cathode. Alternatively, the light-emitting element ED may be a quantum-dot light-emitting element including a quantum-dot light-emitting layer disposed between the anode and the cathode. Alternatively, the light-emitting element ED may be a micro-light-emitting element including a micro-LED disposed between the anode and the cathode. The light-emitting element ED will hereinafter be described as being an OLED having an organic light-emitting layer positioned between the anode and the cathode.

The anode of the light-emitting element ED may also be referred to as a pixel electrode, and the cathode of the light-emitting element ED may also be referred to as a common electrode CE.

The anode of the light-emitting element ED may be connected to a first electrode of the fourth transistor ST4 and a second electrode of the sixth transistor ST6, and the cathode of the light-emitting element ED may be connected to the second driving voltage line VSL. Parasitic capacitance Cel may be formed between the anode and the cathode of the light-emitting element ED.

The first transistor ST1 is turned on by an initialization scan signal from the k-th display initialization line GILk and connects the gate electrode of the driving transistor DT to the initialization voltage line VIL. As a result, an initialization voltage from the initialization voltage line VIL may be applied to the gate electrode of the driving transistor DT. The gate electrode of the first transistor ST1 may be connected to the k-th initialization line GILk, the first electrode of the first transistor ST1 may be connected to the gate electrode of the driving transistor DT, and the second electrode of the first transistor ST1 may be connected to the initialization voltage line VIL.

The second transistor ST2 is turned on by a display write signal from the k-th display write line GWLk and connects the first electrode of the driving transistor DT to a j-th data line Dj. As a result, a data voltage from the j-th data line may be applied to the first electrode of the driving transistor DT. The gate electrode of the second transistor ST2 may be connected to the k-th display write line GWLk, the first electrode of the second transistor ST2 may be connected to the first electrode of the driving transistor DT, and the second electrode of the second transistor ST2 may be connected to the j-th data line Dj.

The third transistor ST3 is turned on by the display write signal from the k-th display write line GWLk and connects the gate electrode and the second electrode of the driving transistor DT. When the gate electrode and the second electrode of the driving transistor DT are connected, the driving transistor DT operates as a diode (e.g., the driving transistor DT is diode-connected). The gate electrode of the third transistor ST3 may be connected to the k-th display write line GWLk, the first electrode of the third transistor ST3 may be connected to the second electrode of the driving transistor DT, and the second electrode of the third transistor ST3 may be connected to the gate electrode of the diving transistor DT.

The fourth transistor ST4 is turned on by a display control signal from the k-th display control line GCLk and connects the anode of the light-emitting element ED to the initialization voltage line VIL. The initialization voltage from the initialization voltage line VIL may be applied to the anode of the light-emitting element ED. The gate electrode of the fourth transistor ST4 may be connected to the k-th display control line GCLK, the first electrode of the fourth transistor ST4 may be connected to the anode of the light-emitting element ED, and the second electrode of the fourth transistor ST4 may be connected to the initialization voltage line VIL.

The fifth transistor ST5 is turned on by an emission signal from the k-th emission line Elk and connects the first electrode of the driving transistor DT to the first driving voltage line VDL. The gate electrode of the fifth transistor ST5 may be connected to the k-th emission line ELk, the first electrode of the fifth transistor ST5 may be connected to the first driving voltage line VDL, and the second electrode of the fifth transistor ST5 may be connected to the first electrode of the driving transistor DT.

The sixth transistor ST6 is disposed between the second electrode of the driving transistor DT and the anode of the light-emitting element ED. The sixth transistor ST6 is turned on by an emission control signal from the k-th emission line Elk and connects the second electrode of the driving transistor DT to the anode of the light-emitting element ED. The gate electrode of the sixth transistor ST6 may be connected to the k-th emission line Elk, the first electrode of the sixth transistor ST6 may be connected to the second electrode of the driving transistor DT, and the second electrode of the sixth transistor ST6 may be connected to the anode of the light-emitting element ED.

When the fifth and sixth transistors ST5 and ST6 are both turned on, the driving current Ids of the driving transistor DT may flow into the light-emitting element ED according to the data voltage applied to the gate electrode of the driving transistor DT.

The capacitor CST is formed between the gate electrode of the driving transistor DT and the first driving voltage line VDL. The first electrode of the capacitor CST may be connected to the gate electrode of the driving transistor DT, and the second electrode of the capacitor CST may be connected to the first driving voltage line VDL.

When the first electrodes of the driving transistor DT and the first through sixth transistors ST1 through ST6 are source electrodes, the second electrodes of the driving transistor DT and the first through sixth transistors ST1 through ST6 are drain electrodes. Conversely, when the first electrodes of the driving transistor DT and the first through sixth transistors ST1 through ST6 are drain electrodes, the second electrodes of the driving transistor DT and the first through sixth transistors ST1 through ST6 are source electrodes. The first electrodes and the second electrodes of the driving transistor DT and the first through sixth transistors ST1 through ST6 may be referred to as source electrodes and drain electrodes, respectively, or vice versa, depending on the direction in which multiple carriers move within the semiconductor layers. The first electrodes and the second electrodes of the driving transistor DT and the first through sixth transistors ST1 through ST6 may also be referred to as source/drain electrodes. The first electrodes and the second electrodes of the driving transistor DT and the first through sixth transistors ST1 through ST6 may also be referred to as first source/drain electrodes and second source/drain electrodes, respectively, if it is necessary to distinguish them.

The active layers of the driving transistor DT and the first through sixth transistors ST1 through ST6 may be formed of one of polysilicon, amorphous silicon, and an oxide semiconductor. FIG. 3 illustrates the driving transistor DT and the first through sixth transistors ST1 through ST6 as being p-type metal-oxide semiconductor field-effect transistors (MOSFETs), but the present disclosure is not limited thereto. Alternatively, the driving transistor DT and the first through sixth transistors ST1 through ST6 may be formed as N-type MOSFETs.

The pixel circuit PXC may have a “7T1C” configuration consisting of seven transistors and one capacitor, and the numbers of transistors and capacitors that form the pixel circuit PXC may vary. For example, the pixel circuit PXC may have a “5T2C” configuration consisting of five transistors and two capacitors.

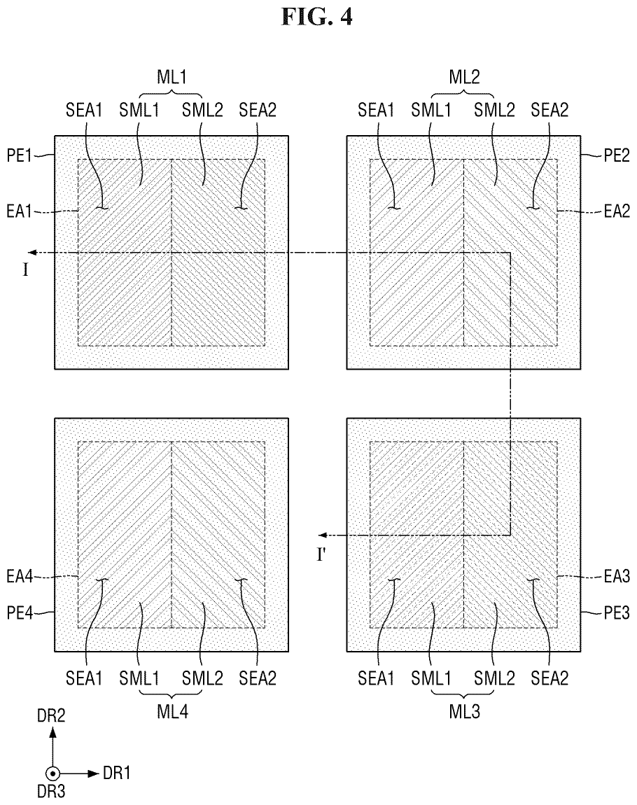

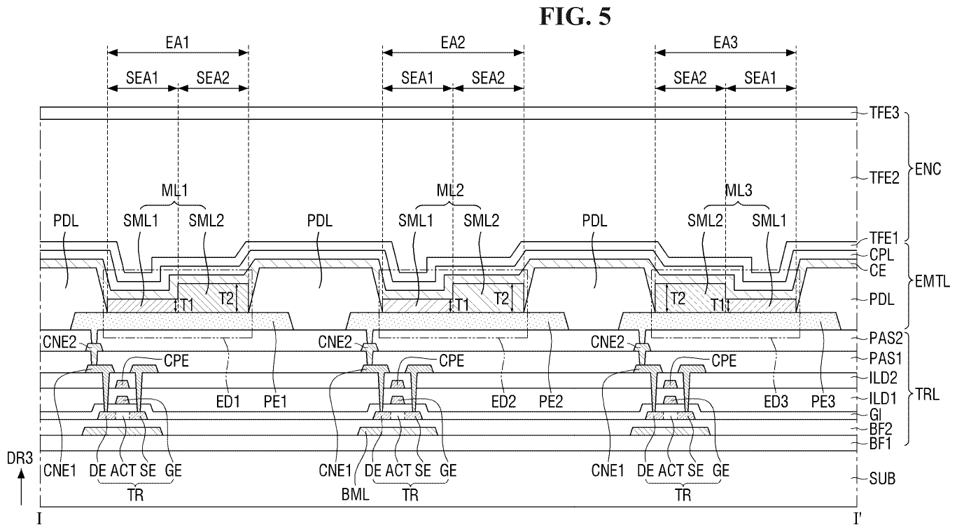

FIG. 4 is a plan view of multiple pixels of the display device of FIG. 1. FIG. 5 is a cross-sectional view taken along the line I-I′ of FIG. 4.

Referring to FIG. 5, the display device 1 may include a substrate SUB, a transistor layer TRL, a light-emitting element layer EMTL, and an encapsulation layer ENC.

The substrate SUB may be a base substrate or member. The substrate SUB may be a flexible substrate, which is bendable, foldable, and/or rollable. For example, the substrate SUB may include a polymer resin such as polyimide (PI), but the present disclosure is not limited thereto. In another example, the substrate SUB may include a glass material or a metal material. In another example, the substrate SUB may be a semiconductor pattern formed on a silicon (Si) substrate. In another example, the substrate SUB may be a Si semiconductor substrate formed by a complementary metal-oxide semiconductor (CMOS) process. The substrate SUB may include a monocrystalline Si wafer, a polycrystalline Si wafer, and/or an amorphous Si wafer or may be a germanium (Ge) substrate or a silicon-germanium (SiGe) substrate.

The transistor layer TRL may include a first buffer layer BF1, a lower metal layer BML, a second buffer layer BF2, transistors TR, a gate insulating layer GI, a first interlayer insulating layer ILD1, capacitor electrodes CPE, a second interlayer insulating layer ILD2, first connection electrodes CNE1, a first passivation layer PAS1, second connection electrodes CNE2, and a second passivation layer PAS2.

The first buffer layer BF1 may be disposed on the substrate SUB. The first buffer layer BF1 may include an inorganic film capable of preventing the penetration of the air or moisture. For example, the first buffer layer BF1 may include a plurality of inorganic films that are alternately stacked.

The lower metal layer BML may be disposed on the first buffer layer BF1. For example, the lower metal layer BML may be formed as a single layer or multilayer containing molybdenum (Mo), aluminum (Al), chromium (Cr), gold (Au), titanium (Ti), nickel (Ni), neodymium (Nd), copper (Cu), and/or an alloy thereof.

The second buffer layer BF2 may cover the first buffer layer BF1 and the lower metal layer BML. The second buffer layer BF2 may include an inorganic film capable of preventing the penetration of the air or moisture. For example, the second buffer layer BF2 may include a plurality of inorganic films that are alternately stacked.

The transistors TR may be disposed on the second buffer layer BF2 and may form the pixel circuits of pixels PX. For example, the transistors TR may be driving transistors (“DT” of FIG. 4) of pixel circuits (“PXC” of FIG. 4). The transistors TR may include semiconductor layers ACT, source electrodes SE, drain electrodes DE, and gate electrodes GE.

The semiconductor layers ACT may be disposed on the second buffer layer BF2. The semiconductor layers ACT may overlap with the lower metal layers BML and the gate electrodes GE in the thickness direction (e.g., the third direction DR3) and may be insulated from the gate electrodes GE by a gate insulating layer GI (i.e., a gate insulating film). The source electrodes SE and the drain electrodes DE may be formed by transforming certain parts of the semiconductor layers ACT into conductive materials.

The gate electrodes GE may be disposed on the gate insulating layer GI. The gate electrodes GE may overlap with the semiconductor layers ACT with the gate insulating layer GI interposed therebetween.

The gate insulating layer GI may be disposed on the semiconductor layers ACT and the second buffer layer BF2. For example, the gate insulating layer GI may cover the semiconductor layers ACT and the second buffer layer BF2 and may insulate the semiconductor layers ACT and the gate electrodes GE. The gate insulating layer GI may include contact holes that are penetrated by the first connection electrodes CNE1.

The first interlayer insulating layer ILD1 may cover the gate electrodes GE and the gate insulating layer GI. The first interlayer insulating layer ILD1 may include contact holes that are penetrated by the first connection electrodes CNE1. The contact holes of the first interlayer insulating layer ILD1 may be linked with the contact holes of the gate insulating layer GI and contact holes of the second interlayer insulating layer ILD2.

The capacitor electrodes CPE may be disposed on the first interlayer insulating layer ILD1. The capacitor electrodes CPE may overlap with the gate electrodes GE in the thickness direction (e.g., the third direction DR3). The capacitor electrodes CPE and the gate electrodes GE may form capacitances. For example, the gate electrodes GE may correspond to the first electrodes of capacitors (“CST” of FIG. 3), and the capacitor electrodes CPE may correspond to the second electrodes of the capacitors (“CST” of FIG. 3).

The second interlayer insulating layer ILD2 may cover the capacitor electrodes CPE and the first interlayer insulating layer ILD1. The second interlayer insulating layer ILD2 may include contact holes that are penetrated by the first connection electrodes CNE1. The contact holes of the second interlayer insulating layer ILD2 may be linked with the contact holes of the first interlayer insulating layer ILD1 and the contact holes of the gate insulating layer GI.

The first connection electrodes CNE1 may be disposed on the second interlayer insulating layer ILD2. The first connection electrodes CNE1 may electrically connect the drain electrodes DE of the transistor TR and the second connection electrodes CNE2. The first connection electrodes CNE1 may be in contact with the drain electrodes DE of the transistors TR by being inserted into the contact holes of each of the second interlayer insulating layer ILD2, the first interlayer insulating layer ILD1, and the gate insulating layer GI.

The first passivation layer PAS1 may cover the first connection electrodes CNE1 and the second interlayer insulating layer ILD2. The first passivation layer PAS1 may protect the transistors TR. The first passivation layer PAS1 may include contact holes that are penetrated by the second connection electrodes CNE2.

The second connection electrodes CNE2 may be disposed on the first passivation layer PAS1. The second connection electrodes CNE2 may electrically connect the first connection electrodes CNE1 and the first electrodes (or first, second, third, and fourth pixel electrodes PE1, PE2, PE3, and PE4) of first, second, and third light-emitting elements ED1, ED2, and ED3 and a fourth light-emitting element. The second connection electrodes CNE2 may be in contact with the first connection electrodes CNE1 by being inserted into the contact holes of the first passivation layer PAS1.

The second passivation layer PAS2 may cover the second connection electrodes CNE2 and the first passivation layer PAS1. The second passivation layer PAS2 may include contact holes that are penetrated by the pixel electrodes PE1, PE2, PE3, and PE4.

The light-emitting element layer EMTL may be disposed on the transistor layer TRL. The light-emitting element layer EMTL may include the first, second, and third light-emitting elements ED1, ED2, and ED3 and a bank PDL. The first, second, and third light-emitting elements ED1, ED2, and ED3 and the fourth light-emitting element may include the first, second, third, and fourth pixel electrodes PE1, PE2, PE3, and PE4, respectively, first, second, third, and fourth middle layers ML1, ML2, ML3, and ML4, respectively, and a common electrode CE.

The display device 1 may include a plurality of emission regions (EA1, EA2, EA3, and EA4), which are disposed in the display area DA. The emission regions (EA1, EA2, EA3, and EA4) may include first, second, third, and fourth emission regions EA1, EA2, EA3, and EA4, which emit different colors of light. The fourth emission region EA4 may emit the same color of light as the second emission region EA2. The first, second, third, and fourth emission regions EA1, EA2, EA3, and EA4 may emit red light, blue light, green light, and blue light, respectively, and the color of light emitted by each of the first, second, third, and fourth emission regions EA1, EA2, EA3, and EA4 may vary depending on the type of light-emitting element disposed in the light-emitting element layer EMTL. For example, the first emission region EA1 may emit red light, the second and fourth emission regions EA2 and EA4 may emit blue light, and the third emission region EA3 may emit green light. However, the present disclosure is not limited to this example.

The first, second, third, and fourth emission regions EA1, EA2, EA3, and EA4 may be defined by a plurality of openings, which are formed in the bank PDL of the light-emitting element layer EMTL. The first, second, third, and fourth emission regions EA1, EA2, EA3, and EA4 may have the same area or size. For example, the first, second, third, and fourth emission regions EA1, EA2, EA3, and EA4 may all have the same area, but the present disclosure is not limited thereto. Alternatively, the first, second, third, and fourth emission regions EA1, EA2, EA3, and EA4 may have different areas or sizes. The intensity of light emitted by each of the first, second, third, and fourth emission regions EA1, EA2, EA3, and EA4 may vary depending on the area of the corresponding emission region, and the color of a screen displayed by the display device 1 may be controlled by adjusting the area of each of the first, second, third, and fourth emission regions EA1, EA2, EA3, and EA4. FIG. 5 illustrates the first, second, third, and fourth emission regions EA1, EA2, EA3, and EA4 as having the same area, but the present disclosure is not limited thereto. The area of each of the first, second, third, and fourth emission regions EA1, EA2, EA3, and EA4 can be freely adjusted in accordance with a screen color required by the display device 1. The areas of the first, second, third, and fourth emission regions EA1, EA2, EA3, and EA4 may be related to factors, such as optical efficiency and the lifespan of light-emitting elements, and may also be subject to a trade-off relationship with external reflection, and the areas of the first, second, third, and fourth emission regions EA1, EA2, EA3, and EA4 can be adjusted in consideration of these factors.

In the display device 1, one first emission region EA1, one second emission region EA2, one third emission region EA3, and one fourth emission region EA4 that are positioned adjacent to one another may form a single unit pixel together. A single unit pixel may represent a white gradation by including multiple emission regions that emit different colors of light, but the present disclosure is not limited thereto. The combination of the first, second, third, and fourth emission regions EA1, EA2, EA3, and EA4 that form a single unit pixel may vary depending on the layout of the first, second, third, and fourth emission regions EA1, EA2, EA3, and EA4 and the color of light emitted by each of the first, second, third, and fourth emission regions EA1, EA2, EA3, and EA4.

The display device 1 may include the first, second, and third light-emitting elements ED1, ED2, and ED3, which are disposed in the first, second, and third emission regions EA1, EA2, and EA3, respectively, and the fourth light-emitting element, which is disposed in the fourth emission region EA4. For example, the light-emitting element layer EMTL of the display device 1 may include the first, second, and third light-emitting elements ED1, ED2, and ED3, which are disposed in the first, second, and third emission regions EA1, EA2, and EA3, respectively, and the fourth light-emitting element, which is disposed in the fourth emission region EA4. The first, second, and third light-emitting elements ED1, ED2, and ED3 may include the first, second, and third pixel electrodes PE1, PE2, and PE3, respectively, the first, second, and third middle layers ML1, ML2, and ML3, respectively, and the common electrode CE (or a second electrode), and the fourth light-emitting element may include the fourth pixel electrode PE4, the fourth middle layer ML4, and the common electrode CE.

The first, second, third, and fourth emission regions EA1, EA2, EA3, and EA4 that form a single unit pixel may provide various colors of light through the first, second, and third light-emitting elements ED1, ED2, and ED3 and the fourth light-emitting element, which emit different colors of light. For example, a unit pixel may include first, second, third, and fourth pixels that are disposed adjacent to one another, the first, second, and third pixels may include the first, second, and third light-emitting elements ED1, ED2, and ED3, respectively, which emit red light, blue light, and green light, respectively, and the fourth pixel may include the fourth light-emitting element, which emits blue light. In this example, the unit pixel can provide various colors of light by mixing the red light provided by the first light-emitting element ED1 of the first pixel, the blue light provided by the second light-emitting element ED2 of the second pixel and the fourth light-emitting element of the fourth pixel, and the green light provided by the third light-emitting element ED3 of the third pixel.

The first, second, third, and fourth pixel electrodes PE1, PE2, PE3, and PE4 may be disposed on the second passivation layer PAS2. For example, the first, second, third, and fourth pixel electrodes PE1, PE2, PE3, and PE4 may be positioned to correspond to the first, second, third, and fourth emission regions EA1, EA2, EA3, and EA4, respectively.

The first, second, third, and fourth pixel electrodes PE1, PE2, PE3, and PE4 may be electrically connected to the drain electrodes DE of the transistors TR through the first connection electrodes CNE1 and the second connection electrodes CNE2. For example, the first pixel electrode PE1 may be connected to the drain electrode of the transistor TR of the first pixel through first and second connection electrodes CNE1 and CNE2, the second pixel electrode PE2 may be connected to the drain electrode of the transistor TR of the second pixel through first and second connection electrodes CNE1 and CNE2, the third pixel electrode PE3 may be connected to the drain electrode of the transistor of the third pixel through first and second connection electrodes CNE1 and CNE2, and the fourth pixel electrode PE4 may be connected to the drain electrode of the transistor of the fourth pixel through first and second connection electrodes CNE1 and CNE2.

Each of the first, second, third, and fourth pixel electrodes PE1, PE2, PE3, and PE4 may have a structure in which a high work function material layer containing a material with a high work function, such as indium tin oxide (ITO), indium zinc oxide (IZO), zinc oxide (ZnO), or indium oxide (In₂O₃), and a reflective material layer containing silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), and/or a mixture thereof are stacked. The high work function material layer may be disposed above the reflective material layer, close to first, second, and third light-emitting layers EL1, EL2, and EL3. For example, the first, second, third, and fourth pixel electrodes PE1, PE2, PE3, and PE4 may have a multilayer structure such as ITO/Mg, ITO/MgF, ITO/Ag, or ITO/Ag/ITO, but the present disclosure is not limited thereto.

The bank PDL (or a pixel-defining film) may be disposed on the first, second, third, and fourth pixel electrodes PE1, PE2, PE3, and PE4.

The bank PDL may define the first, second, third, and fourth emission regions EA1, EA2, EA3, and EA4 of the first, second, third, and fourth pixels. To this end, the bank PDL may be disposed on the second passivation layer PAS2 to expose parts of the first, second, third, and fourth pixel electrodes PE1, PE2, PE3, and PE4. For example, the bank PDL may cover the edges of each of the first, second, third, and fourth pixel electrodes PE1, PE2, PE3, and PE4. The bank PDL may be formed as an organic film containing an acrylic resin, an epoxy resin, a phenolic resin, a polyamide resin, and/or a polyimide resin.

The first, second, third, and fourth middle layers ML1, ML2, ML3, and ML4 may be disposed on the first, second, third, and fourth pixel electrodes PE1, PE2, PE3, and PE4, respectively. In a plan view, the first middle layer ML1 may have, for example, a rectangular shape. First and second sub-middle layers SML1 and SML2 of the first middle layer ML1 may have a rectangular shape that is longer in the second direction DR2 than in the first direction DR1. In a plan view, the first and second sub-middle layers SML1 and SML2 of the first middle layer ML1 may face each other and may be in contact with each other. Also, the first and second sub-middle layers SML1 and SML2 of the first middle layer ML1 may be positioned to face each other in the first direction DR1. The second, third, and fourth middle layers ML2, ML3, and ML4 may have the same shape as the first middle layer ML1.

The common electrode CE may be disposed on the first, second, third, and fourth middle layers ML1, ML2, ML3, and ML4. For example, the common electrode CE may be positioned on the first, second, third, and fourth middle layers ML1, ML2, ML3, and ML4 to overlap with the first, second, third, and fourth pixel electrodes PE1, PE2, PE3, and PE4, the first, second, third, and fourth emission regions EA1, EA2, EA3, and EA4, and the bank PDL. The common electrode CE may be a common layer that is used in common for the first, second, and third light-emitting elements ED1, ED2, and ED3 and the fourth light-emitting element. In other words, the first, second, and third light-emitting elements ED1, ED2, and ED3 and the fourth light-emitting element may share the common electrode CE. In a top emission structure, the common electrode CE may be formed of a transparent conductive oxide (TCO) capable of transmitting light therethrough, such as ITO or IZO, or a semi-transmissive metal material such as Mg, Ag, or an alloy thereof. In a case where the common electrode CE is a semi-transmissive metal material, the light emission efficiency of the display device 1 can be improved due to micro-cavities.

A capping layer CPL may be disposed on the common electrode CE. The capping layer CPL may include an inorganic insulating material. For example, the capping layer CPL may include aluminum oxide, titanium oxide, tantalum oxide, hafnium oxide, zinc oxide, silicon oxide, silicon nitride, and/or silicon oxynitride.

An encapsulation layer ENC may be disposed on the capping layer CPL. The encapsulation layer ENC may cover the top surface and the side surfaces of the light-emitting element layer EMTL and may protect the light-emitting element layer EMTL. The encapsulation layer ENC may include at least one inorganic film and at least one organic film for encapsulating the light-emitting element layer EMTL. Specifically, the encapsulation layer ENC may include at least one inorganic films for preventing the penetration of oxygen or moisture into the light-emitting element layer EMTL. The encapsulation layer ENC may include at least one organic film for protecting the light-emitting element layer EMTL from a foreign material such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be disposed on the capping layer CPL, the encapsulation organic film TFE2 may be disposed on the first encapsulation inorganic film TFE1, and the second encapsulation inorganic film TFE3 may be disposed on the encapsulation organic film TFE2. The first and second encapsulation inorganic films TFE1 and TFE3 may be formed as multifilms in which one or more inorganic films selected from among a silicon nitride layer, a silicon oxynitride layer, a silicon oxide layer, a titanium oxide layer, and/or an aluminum oxide layer are alternately stacked. The encapsulation organic film TFE2 may be formed as an organic film containing an acrylic resin, an epoxy resin, a phenolic resin, a polyamide resin, or a polyimide resin.

The first light-emitting element ED1 may include the first pixel electrode PE1, the common electrode CE, and the first middle layer ML1. The first middle layer ML1 may be disposed between the first pixel electrode PE1 and the common electrode CE. The first middle layer ML1 may be disposed on the first pixel electrode PE1 to overlap with the first pixel electrode PE1.

The second light-emitting element ED2 may include the second pixel electrode PE2, the common electrode CE, and the second middle layer ML2. The second middle layer ML2 may be disposed between the second pixel electrode PE2 and the common electrode CE. The second middle layer ML2 may be disposed on the second pixel electrode PE2 to overlap with the second pixel electrode PE2.

The third light-emitting element ED3 may include the third pixel electrode PE3, the common electrode CE, and the third middle layer ML3. The third middle layer ML3 may be disposed between the third pixel electrode PE3 and the common electrode CE. The third middle layer ML3 may be disposed on the third pixel electrode PE3 to overlap with the third pixel electrode PE3.

The fourth light-emitting element may include the fourth pixel electrode PE4, the common electrode CE, and the fourth middle layer ML4. The fourth middle layer ML4 may be disposed between the fourth pixel electrode PE4 and the common electrode CE. The fourth middle layer ML4 may be disposed on the fourth pixel electrode PE4 to overlap with the fourth pixel electrode PE4.

In the example of FIGS. 4-5, each of the first, second, third, and fourth middle layers ML1, ML2, ML3, and ML4 may have different thicknesses in its corresponding emission region. Each of the first, second, third, and fourth middle layers ML1, ML2, ML3, and ML4 may have different thicknesses in the emission region overlapping with its corresponding pixel electrode. For example, the first middle layer ML1, which overlaps with (or is in contact with) the first pixel electrode PE1 and is disposed in the first emission region EA1, may have different thicknesses, i.e., first and second thicknesses T1 and T2 (where T2>T1), in the first emission region EA1. For example, the second middle layer ML2, which overlaps with (or is in contact with) the second pixel electrode PE2 and is disposed in the second emission region EA2, may have different thicknesses, i.e., the first and second thicknesses T1 and T2 (where T2>T1), in the second emission region EA2. For example, the third middle layer ML3, which overlaps with (or is in contact with) the third pixel electrode PE3 and is disposed in the third emission region EA3, may have different thicknesses, i.e., the first and second thicknesses T1 and T2 (where T2>T1), in the third emission region EA3. For example, the fourth middle layer ML4, which overlaps with (or is in contact with) the fourth pixel electrode PE4 and is disposed in the fourth emission region EA4, may have different thicknesses in the fourth emission region EA4. Here, the term “thickness” refers to the dimension measured in the third direction DR3.

Each of the first, second, third, and fourth middle layers ML1, ML2, ML3, and ML4 may include a plurality of sub-middle layers. For example, referring to FIG. 5, the first middle layer ML1 may include the first and second sub-middle layers SML1 and SML2, which are disposed in first and second sub-emission regions SEA1 and SEA2, respectively, of the first emission region EA1. A second thickness T2 of the second sub-middle layer SML2 of the first middle layer ML1 may be greater than a first thickness T1 of the first sub-middle layer SML1 of the first middle layer ML1 (i.e., T2>T1).

For example, referring to FIG. 5, the second middle layer ML2 may include first and second sub-middle layers SML1 and SML2, which are disposed in first and second sub-emission regions SEA1 and SEA2, respectively, of the second emission region EA2. A second thickness T2 of the second sub-middle layer SML2 of the second middle layer ML2 may be greater than a first thickness T1 of the first sub-middle layer SML1 of the second middle layer ML2 (i.e., T2>T1).

For example, referring to FIG. 5, the third middle layer ML3 may include first and second sub-middle layers SML1 and SML2, which are disposed in first and second sub-emission regions SEA1 and SEA2, respectively, of the third emission region EA3. A second thickness T2 of the second sub-middle layer SML2 of the third middle layer ML3 may be greater than a first thickness T1 of the first sub-middle layer SML1 of the third middle layer ML3 (i.e., T2>T1).

For example, referring to FIG. 5, the fourth middle layer ML4 may include first and second sub-middle layers SML1 and SML2, which are disposed in first and second sub-emission regions SEA1 and SEA2, respectively, of the fourth emission region EA4. The second sub-middle layer SML2 of the fourth middle layer ML4 may be thicker than the first sub-middle layer SML1 of the fourth middle layer ML4.

The thicknesses of the first and second sub-middle layers SML1 and SML2 of each of the first, second, third, and fourth middle layers ML1, ML2, ML3, and ML4 may refer to the dimensions measured in the third direction DR3.

Each of the first, second, third, and fourth middle layers ML1, ML2, ML3, and ML4 may include a light-emitting layer (e.g., a first red light-emitting layer REML1) and first and second functional layers positioned above and below the light-emitting layer. The first functional layer may include, for example, a hole transport layer and/or a hole injection layer. The second functional layer, which is disposed on the light-emitting layer, may be optional. That is, each of the first, second, third, and fourth middle layers ML1, ML2, ML3, and ML4 may not include the second functional layer. The second functional layer may include an electron transport layer and/or an electron injection layer.

Each of the first, second, third, and fourth middle layers ML1, ML2, ML3, and ML4 may include two or more light-emitting units, which are sequentially stacked between the first, second, third, or fourth pixel electrode PE1, PE2, PE3, or PE4 and the common electrode CE, and a charge generation layer, which is disposed between the two light-emitting units. In this case, the first, second, and third light-emitting elements ED1, ED2, and ED3 and the fourth light-emitting element may be tandem light-emitting elements. As each of the first, second, and third light-emitting elements ED1, ED2, and ED3 and the fourth light-emitting element has a structure where multiple light-emitting units are stacked, the color purity and light emission efficiency of the display device 1 can be improved.

Each of the two light-emitting units included in each of the first, second, third, and fourth middle layers ML1, ML2, ML3, and ML4 may include a light-emitting layer and first and second functional layers positioned below and above the light-emitting layer. The charge generation layer included in each of the first, second, third, and fourth middle layers ML1, ML2, ML3, and ML4 may include a negative charge generation layer and a positive charge generation layer. Due to the presence of the negative charge generation layer and the positive charge generation layer, the light emission efficiency of OLEDs, which are tandem light-emitting elements equipped with multiple light-emitting layers, can be further improved.

The negative charge generation layer may be an n-type charge generation layer. The negative charge generation layer may supply electrons. The negative charge generation layer may include a host and a dopant. The host of the negative charge generation layer may include an organic material, while the dopant of the negative charge generation layer may include a metal material. The positive charge generation layer may be a p-type CGL. The positive charge generation layer may supply holes. The positive charge generation layer may include a host and a dopant. The host of the positive charge generation layer may include an organic material, and the dopant of the positive charge generation layer may include a metal material.

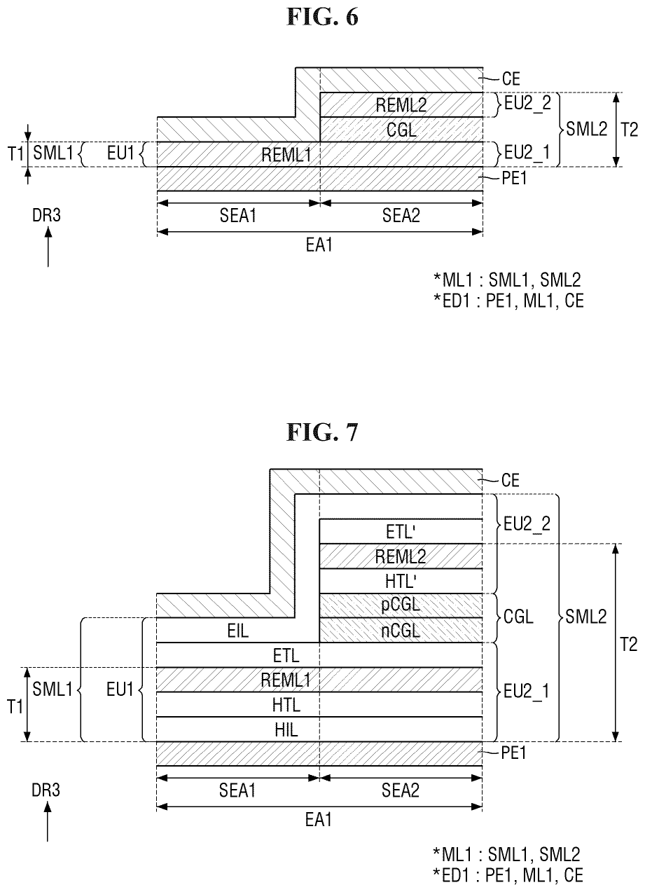

FIG. 6 is a detailed cross-sectional view of a first light-emitting element of the display device of FIG. 5.

Referring to FIG. 6, a first light-emitting element ED1 may include a first pixel electrode PE1, a common electrode CE, and a first middle layer ML1.

The first middle layer ML1 may be disposed between the first pixel electrode PE1 and the common electrode CE. The first middle layer ML1 may include first and second sub-middle layers SML1 and SML2.

The first sub-middle layer SML1 may be disposed in a first sub-emission region SEA1 of a first emission region EA1, and the second sub-middle layer SML2 may be disposed in a second sub-emission region SEA2 of the first emission region EA1.

The first sub-middle layer SML1 may include a first light-emitting unit EU1, which is on the first pixel electrode PE1. The first light-emitting unit EU1 may include a first red light-emitting layer REML1. In other words, the first sub-middle layer SML1 may include the first red light-emitting layer REML1, which is disposed in the first sub-emission region SEA1 between the first pixel electrode PE1 and the common electrode CE.

The second sub-middle layer SML2 may include a first light-emitting unit EU2_1, which is on the first pixel electrode PE1, a charge generation layer CGL, which is on the first light-emitting unit EU2_1, and a second light-emitting unit EU2_2, which is on the charge generation layer CGL. The first light-emitting unit EU2_1 of the second sub-middle layer SML2 may include the first red light-emitting layer REML1, and the second light-emitting unit EU2_2 of the second sub-middle layer SML2 may include a second red light-emitting layer REML2. In other words, the second sub-middle layer SML2 may include the first red light-emitting layer REML1, the charge generation layer CGL, and the second light-emitting layer REML2, which are sequentially stacked in the second sub-emission region SEA2 between the first pixel electrode PE1 and the common electrode CE along the third direction DR3.

The first red light-emitting layer REML1 may be a common layer that is positioned in common for the first and second sub-middle layers SML1 and SML2. In other words, the first and second sub-middle layers SML1 and SML2 may share the first red light-emitting layer REML1.

The first and second sub-middle layers SML1 and SML2 may include different numbers of light-emitting layers. For example, the number of red light-emitting layers included in the second sub-middle layer SML2 may be greater than the number of red light-emitting layers included in the first sub-middle layer SML1. For example, as illustrated in FIG. 6, the first sub-middle layer SML1 may include one red light-emitting layer (i.e., the first red light-emitting layer REML1), whereas the second sub-middle layer SML2 may include two red light-emitting layers (i.e., the first red light-emitting layer REML1 and the second red light-emitting layer REML2).

The first and second sub-middle layers SML1 and SML2 may have different thicknesses. For example, a second thickness T2 of the second sub-middle layer SML2 may be greater than a first thickness T1 of the first sub-middle layer SML1. In other words, a second thickness T2 of the second sub-middle layer SML2 may be greater than a first thickness T1 of the first sub-middle layer SML1 (i.e., T2>T1) because the second sub-middle layer SML2 further includes the charge generation layer CGL and the second red light-emitting layer REML2, compared to the first sub-middle layer SML1.

The first and second red light-emitting layers REML1 and REML2 may both emit red light.

The first red light-emitting layer REML1 may include an organic material layer. The organic material layer of the first red light-emitting layer REML1 may include a host material containing carbazole biphenyl (CBP) or 1,3-bis(carbazol-9-yl (mCP) and may be a phosphorescent material including a dopant containing at least one selected from among bis(1-phenylisoquinoline) acetylacetonate iridium (PIQIr (acac)), bis(1-phenylquinoline) acetylacetonate iridium (PQIr (acac)), tris(1-phenylquinoline) iridium (PQIr), and/or octaethylporphyrin platinum (PtOEP). Alternatively, the organic material layer of the first red light-emitting layer REML1 may be a fluorescent material containing PBD: Eu(DBM)₃(Phen) and/or perylene, but the present disclosure is not limited thereto.

The second red light-emitting layer REML2 may include an organic material layer. The organic material layer of the second red light-emitting layer REML2 may be the same as the organic material layer of the first red light-emitting layer REML1.

As the number of red light-emitting layers included in the first sub-middle layer SML1 differs from the number of red light-emitting layers included in the second sub-middle layer SML2, the first and second sub-middle layers SML1 and SML2 may emit red light with different gray levels (or luminances) in accordance with the electric field between the first pixel electrode PE1 and the common electrode CE. For example, a sub-middle layer that has a relatively smaller number of light-emitting layers may emit light first in response to a voltage (e.g., a pixel voltage) applied to the first pixel electrode PE1. For example, when a pixel voltage is applied to the first pixel electrode PE1, the first sub-middle layer SML1 may emit red light with a second gray level, and the second sub-middle layer SML2 may emit red light with a first gray level, which is lower than the second gray level, or darker red light. That is, a sub-middle layer that has a relatively larger number of light-emitting layers may emit red light with a lower gray level for each given pixel voltage. Consequently, a broader range of gray levels can be presented in each pixel even at lower voltages. As a result, the range of data voltages for generating a pixel voltage can be expanded.

FIG. 7 is a detailed cross-sectional view of a first light-emitting element of the display device of FIG. 5.

Referring to FIG. 7, a first light-emitting element ED1 may include a first pixel electrode PE1, a common electrode CE, and a first middle layer ML1.

The first middle layer ML1 may be disposed between the pixel electrode PE1 and the common electrode CE. The first middle layer ML1 may include first and second sub-middle layers SML1 and SML2.

The first sub-middle layer SML1 may be disposed in a first sub-emission region SEA1 of a first emission region EA1, and the second sub-middle layer SML2 may be disposed in a second sub-emission region SEA2 of the first emission region EA1.

The first sub-middle layer SML1 may include a first light-emitting unit EU1, which is on the first pixel electrode PE1. The first light-emitting unit EU1 may include a hole injection layer HIL, a hole transport layer HTL, a first red light-emitting layer REML1, an electron transport layer ETL, and an electron injection layer EIL, which are sequentially stacked in the third direction DR3. In other words, the first sub-middle layer SML1 may include the hole injection layer HIL, the hole transport layer HTL, the first red light-emitting layer REML1, the electron transport layer ETL, and the electron injection layer EIL, which are sequentially stacked in the first sub-emission region SEA1 of the first emission region EA1 along the third direction DR3.

The second sub-middle layer SML2 may include a first light-emitting unit EU2_1, which is disposed on the first pixel electrode PE1 in the second sub-emission region SEA2 of the first emission region EA1, a charge generation layer CGL, which is located on the first light-emitting unit EU2_1, and a second light-emitting unit EU2_2, which is located on the charge generation layer CGL. The first light-emitting unit EU2_1 of the second sub-middle layer SML2 may include the hole injection layer HIL, the hole transport layer HTL, the first red light-emitting layer REML1, and the electron transport layer ETL, which are sequentially stacked in the third direction DR3. The charge generation layer CGL may include a negative charge generation layer nCGL and a positive charge generation layer pCGL, which are sequentially stacked on the electron transport layer ETL along the third direction DR3. The second light-emitting unit EU2_2 may include a hole transport layer HTL′, a second red light-emitting layer REML2, an electron transport layer ETL′, and an electron injection layer EIL, which are sequentially stacked on the positive charge generation layer pCGL along the third direction DR3. In other words, the second sub-middle layer SML2 may include the hole injection layer HIL, the hole transport layer HTL, the first red light-emitting layer REML1, the electron transport layer ETL, the negative charge generation layer nCGL, the positive charge generation layer pCGL, the hole transport layer HTL′, the second red light-emitting layer REML2, the electron transport layer ETL′, and the electron injection layer EIL, which are sequentially stacked in the second sub-emission region SEA2 of the first emission region EA1 between the first pixel electrode PE1 and the common electrode CE along the third direction DR3.

The hole injection layer HIL, the hole transport layer HTL, the first red light-emitting layer REML1, the electron transport layer ETL, and the electron injection layer EIL may be common layers that are positioned in common in the first and second sub-middle layers SML1 and SML2. In other words, the first and second sub-middle layers SML1 and SML2 may share the hole injection layer HIL, the hole transport layer HTL, the first red light-emitting layer REML1, the electron transport layer ETL, and the electron injection layer EIL.

The first and second sub-middle layers SML1 and SML2 may include different numbers of light-emitting layers. For example, the number of red light-emitting layers included in the second sub-middle layer SML2 may be greater than the number of red light-emitting layers included in the first sub-middle layer SML1. For example, as illustrated in FIG. 7, the first sub-middle layer SML1 may include one red light-emitting layer (i.e., the first red light-emitting layer REML1), whereas the second sub-middle layer SML2 may include two red light-emitting layers (i.e., the first and second red light-emitting layers REML1 and REML2).

The first and second sub-middle layers SML1 and SML2 may have different thicknesses. For example, the second sub-middle layer SML2 may be thicker than the first sub-middle layer SML1. For example, when the distance from the bottom surface of the first middle layer ML1 to the top surface of the uppermost light-emitting layer (i.e., the first red light-emitting layer REML1) of the first sub-middle layer SML1 in the third direction DR3 is defined as a first thickness T1 of the first sub-middle layer SML1 and the distance from the bottom surface of the first middle layer ML1 to the top surface of the uppermost light-emitting layer (i.e., the second red light-emitting layer REML2) of the second sub-middle layer SML2 in the third direction DR3 is defined as a second thickness T2 of the second sub-middle layer SML2, the second thickness T2 may be greater than the first thickness T1.

The first and second thicknesses T1 and T2 may be defined as the dimensions measured in the third direction DR3.

The bottom surface of the first middle layer ML1 may be defined as the interface between the first pixel electrode PE1 and the first middle layer ML1 (e.g., the interface between the first pixel electrode PE1 and the hole injection layer HIL of the first middle layer ML1), the top surface of the uppermost light-emitting layer (i.e., the first red light-emitting layer REML1) of the first sub-middle layer SML1 may be defined as the interface between the uppermost light-emitting layer of the first sub-middle layer SML1 and the uppermost electron transport layer (i.e., the electron transport layer ETL) of the first sub-middle layer SML1, and the top surface of the uppermost light-emitting layer (i.e., the second red light-emitting layer REML2) of the second sub-middle layer SML2 may be defined as the interface between the uppermost light-emitting layer (i.e., the second red light-emitting layer REML2) of the second sub-middle layer SML2 and the uppermost electron transport layer (i.e., the electron transport layer ETL′) of the second sub-middle layer SML2.

The uppermost light-emitting layer (i.e., the first red light-emitting layer REML1) of the first sub-middle layer SML1 may be defined as the most distant light-emitting layer of the first sub-middle layer SML1 from the first pixel electrode PE1 in the third direction DR3, the uppermost light-emitting layer (i.e., the second red light-emitting layer REML2) of the second sub-middle layer SML2 may be defined as the most distant light-emitting layer of the second sub-middle layer SML2 from the first pixel electrode PE1 in the third direction DR3, the uppermost electron transport layer (i.e., the electron transport layer ETL′) of the first sub-middle layer SML1 may be defined as the most distant electron transport layer of the first sub-middle layer SML1 from the first pixel electrode PE1 in the third direction DR3, and the uppermost electron transport layer (i.e., the electron transport layer ETL′) of the second sub-middle layer SML2 may be defined as the most distant electron transport layer of the second sub-middle layer SML2 from the first pixel electrode PE1 in the third direction DR3.

The first and second red light-emitting layers REML1 and REML2 of FIG. 7 may be the same as the first and second red light-emitting layers REML1 and REML2, respectively, of FIG. 6.

Referring to FIG. 7, the first sub-middle layer SML1 may have a 1-tandem structure that includes one red light-emitting layer, i.e., the first red light-emitting layer REML1, and the second sub-middle layer SML2 may have a 2-tandem structure that includes two red light-emitting layers, i.e., the first and second red light-emitting layers REML1 and REML2, which are disposed in the first and second light-emitting units EU2_1 and EU2_2, respectively, with one charge generation layer, i.e., the charge generation layer CGL, interposed therebetween.

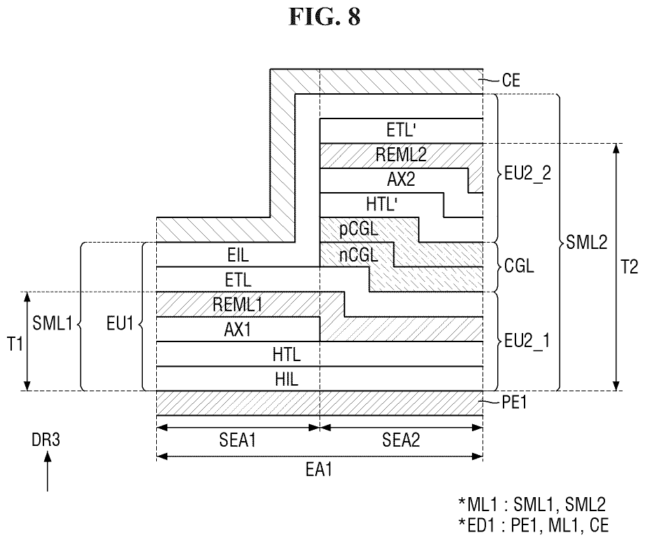

FIG. 8 is a detailed cross-sectional view of a first light-emitting element of the display device of FIG. 5.

A first light-emitting element ED1 of FIG. 8 differs from its counterpart of FIG. 7 in that it further includes at least one of first and second red light auxiliary layers AX1 and AX2. The first light-emitting element ED1 of FIG. 8 will hereinafter be described, highlighting the differences with the first light-emitting element ED1 of FIG. 7.

Referring to FIG. 8, a first red light auxiliary layer AX1 may be further disposed between a hole transport layer HTL and a first red light-emitting layer REML1, and a second red light auxiliary layer AX2 may be further disposed between a hole transport layer HTL′ and a second red light-emitting layer REML2. The first red light auxiliary layer AX1 can improve the light emission efficiency of the first red light-emitting layer REML1, and the second red light auxiliary layer AX2 can improve the light emission efficiency of the second red light-emitting layer REML2. In other words, the first and second red light auxiliary layers AX1 and AX2 can improve the light emission efficiency of the first and second red light-emitting layers REML1 and REML2 by controlling the hole charge balance.

The first light-emitting element ED1 may further include at least one of, for example, an electron blocking layer and a buffer layer. The electron blocking layer and the buffer layer may be disposed between the hole transport layer HTL and the first red light-emitting layer REML1. The electron blocking layer and the buffer layer may be disposed between the hole transport layer HTL′ and the second red light-emitting layer REML2. The electron blocking layer can prevent the injection of electrons into the hole transport layer HTL/HTL′. The buffer layer can compensate for the resonant distance depending on the wavelength of light emitted from the first or second red light-emitting layer REML1 or REML2.

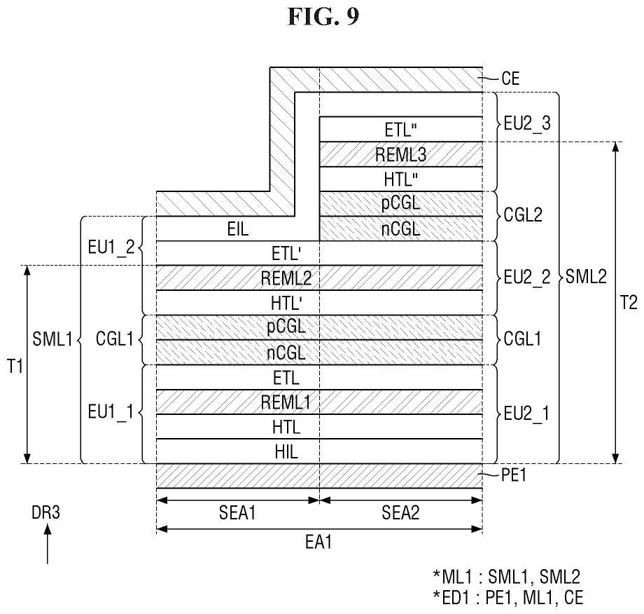

FIG. 9 is a detailed cross-sectional view of a first light-emitting element of the display device of FIG. 5.

Referring to FIG. 9, a first light-emitting element ED1 may include a first pixel electrode PE1, a common electrode CE, and a first middle layer ML1.

The first middle layer ML1 may be disposed between the first pixel electrode PE1 and the common electrode CE. The first middle layer ML1 may include first and second sub-middle layers SML1 and SML2.

The first sub-middle layer SML1 may be disposed in a first sub-emission region SEA1 of a first emission region EA1, and the second sub-middle layer SML2 may be disposed in a second sub-emission region SEA2 of the first emission region EA1.

The first sub-middle layer SML1 may include a first light-emitting unit EU1_1, which is on the first pixel electrode PE1, a first charge generation layer CGL1, which is on the first light-emitting unit EU1_1, and a second light-emitting unit EU1_2, which is on the first charge generation layer CGL1. The first light-emitting unit EU1_1 may include a hole injection layer HIL, a hole transport layer HTL, a first red light-emitting layer REML1, and an electron transport layer ETL, which are sequentially stacked in the third direction DR3. The first charge generation layer CGL1 may include a negative charge generation layer nCGL and a positive charge generation layer pCGL, which are sequentially stacked on the electron transport layer ETL along the third direction DR3. The second light-emitting unit EU1_2 may include a hole transport layer HTL′, a second red light-emitting layer REML2, an electron transport layer ETL′, and an electron injection layer EIL, which are sequentially stacked on the positive charge generation layer pCGL along the third direction DR3. In other words, the first sub-middle layer SML1 may include the hole injection layer HIL, the hole transport layer HTL, the first red light-emitting layer REML1, the electron transport layer ETL, the negative charge generation layer nCGL, the positive charge generation layer pCGL, the hole transport layer HTL′, the second red light-emitting layer REML2, the electron transport layer ETL′, and the electron injection layer EIL, which are sequentially stacked in the first sub-emission region SEA1 between the first pixel electrode PE1 and the common electrode CE along the third direction DR3.

The second sub-middle layer SML2 may include a first light-emitting unit EU2_1, which is on the first pixel electrode PE1, the first charge generation layer CGL1, which is on the first light-emitting unit EU2_1, a second light-emitting unit EU2_2, which is on the first charge generation layer CGL1, a second charge generation layer CGL2, which is on the second light-emitting unit EU2_2, and a third light-emitting unit EU2_3, which is on the second charge generation layer CGL2. The first light-emitting unit EU2_1 may include the hole injection layer HIL, the hole transport layer HTL, the first red light-emitting layer REML1, and the electron transport layer ETL, which are sequentially stacked on the first pixel electrode PE1 along the third direction DR3. The first charge generation layer CGL1 may include a negative charge generation layer nCGL and a positive charge generation layer pCGL, which are sequentially stacked on the electron transport layer ETL along the third direction DR3. The second light-emitting unit EU2_2 may include the hole transport layer HTL′, the second red light-emitting layer REML2, and the electron transport layer ETL′, which are sequentially stacked on the positive charge generation layer pCGL along the third direction DR3. The second charge generation layer CGL2 may include a negative charge generation layer nCGL and a positive charge generation layer pCGL, which are sequentially stacked on the electron transport layer ETL′ along the third direction DR3. The third light-emitting unit EU2_3 may include a hole transport layer HTL″, a third red light-emitting layer REML3, an electron transport layer ETL″, and an electron injection layer EIL, which are sequentially stacked on the positive charge generation layer pCGL of the second charge generation layer CGL2 along the third direction DR3. In other words, the second sub-middle layer SML2 may include the hole injection layer HIL, the hole transport layer HTL, the first red light-emitting layer REML1, the electron transport layer ETL, the negative and positive charge generation layers nCGL and pCGL of the first charge generation layer CGL1, the hole transport layer HTL′, the second red light-emitting layer REML2, the electron transport layer ETL′, the negative and positive charge generation layers nCGL and pCGL of the second charge generation layer CGL2, the hole transport layer HTL″, the third red light-emitting layer REML3, the electron transport layer ETL″, and the electron injection layer EIL, which are sequentially stacked in the second sub-emission region SEA2 between the first pixel electrode PE1 and the common electrode CE along the third direction DR3.

The hole injection layer HIL, the hole transport layer HTL, the first red light-emitting layer REML1, the electron transport layer ETL, the negative and positive charge generation layers nCGL and pCGL of the first charge generation layer CGL1, the hole transport layer HTL′, the second red light-emitting layer REML2, the electron transport layer ETL′, and the electron injection layer EIL may be common layers that are positioned in common in the first and second sub-middle layers SML1 and SML2. In other words, the first and second sub-middle layers SML1 and SML2 may share the hole injection layer HIL, the hole transport layer HTL, the first red light-emitting layer REML1, the electron transport layer ETL, the negative and positive charge generation layers nCGL and pCGL of the first charge generation layer CGL1, the hole transport layer HTL′, the second red light-emitting layer REML2, the electron transport layer ETL′, and the electron injection layer EIL.

The first and second sub-middle layers SML1 and SML2 may include different numbers of light-emitting layers. For example, the number of red light-emitting layers included in the second sub-middle layer SML2 may be greater than the number of red light-emitting layers included in the first sub-middle layer SML1. For example, as illustrated in FIG. 9, the first sub-middle layer SML1 may include two red light-emitting layers (i.e., the first and second red light-emitting layers REML1 and REML2), whereas the second sub-middle layer SML2 may include three red light-emitting layers (i.e., the first, second, and third red light-emitting layers REML1, REML2, and REML3).

The first and second sub-middle layers SML1 and SML2 may have different thicknesses. For example, the second sub-middle layer SML2 may be thicker than the first sub-middle layer SML1. For example, when the distance from the bottom surface of the first middle layer ML1 to the top surface of the uppermost light-emitting layer (i.e., the second red light-emitting layer REML2) of the first sub-middle layer SML1 is defined as a first thickness T1 of the first sub-middle layer SML1 and the distance from the bottom surface of the first middle layer ML1 to the top surface of the uppermost light-emitting layer (i.e., the third red light-emitting layer REML3) of the second sub-middle layer SML2 is defined as a second thickness T2 of the second sub-middle layer SML2, the second thickness T2 may be greater than the first thickness T1.

The first and second red light-emitting layers REML1 and REML2 of FIG. 9 may be the same as the first and second red light-emitting layers REML1 and REML2, respectively, of FIG. 6. The third light-emitting layer REML3 of FIG. 9 may be the same as the first or second red light-emitting layer REML1 or REML2 of FIG. 6.

Referring to FIG. 9, the first sub-middle layer SML1 may have a 2-tandem structure that includes two red light-emitting layers, i.e., the first and second red light-emitting layers REML1 and REML2, which are disposed in the first and second light-emitting units EU1_1 and EU1_2, respectively, with one charge generation layer, i.e., the first charge generation layer CGL1, interposed therebetween, and the second sub-middle layer SML2 may have a 3-tandem structure that includes three red light-emitting layers, i.e., the first, second, and third red light-emitting layers REML1, REML2, and REML3, which are disposed in the first, second, and third light-emitting units EU2_1, EU2_2, and EU2_3, respectively, with two charge generation layers, i.e., the first and second charge generation layers CGL1 and CGL2, interposed therebetween.

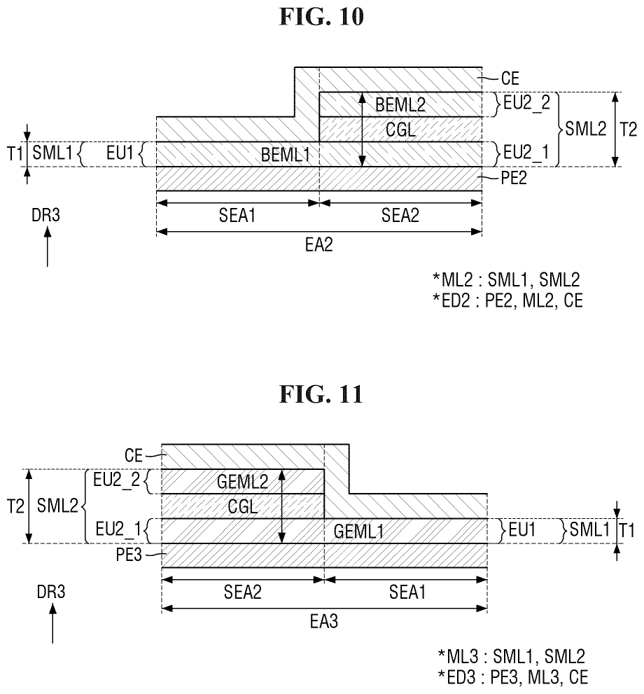

FIG. 10 is a detailed cross-sectional view of a second light-emitting element of the display device of FIG. 5.

Referring to FIG. 10, a second light-emitting element ED2 may include a second pixel electrode PE2, a common electrode CE, and a second middle layer ML2.

The second middle layer ML2 may be disposed between the second pixel electrode PE2 and the common electrode CE. The second middle layer ML2 may include first and second sub-middle layers SML1 and SML2. The first sub-middle layer SML1 may be disposed in a first sub-emission region SEA1 of a second emission region EA2, and the second sub-middle layer SML2 may be disposed in a second sub-emission region SEA2 of the second emission region EA2.

The first sub-middle layer SML1 may include a first light-emitting unit EU1, which is on the second pixel electrode PE2. The first light-emitting unit EU1 may include a first blue light-emitting layer BEML1. In other words, the first sub-middle layer SML1 may include the first blue light-emitting layer BEML1, which is disposed in the first sub-emission region SEA1 between the second pixel electrode PE2 and the common electrode CE.

The second sub-middle layer SML2 may include a first light-emitting unit EU2_1, which is on the second pixel electrode PE2, a charge generation layer CGL, which is on the first light-emitting unit EU2_1, and a second light-emitting unit EU2_2, which is on the charge generation layer CGL. The first light-emitting unit EU2_1 may include the first blue light-emitting layer BEML1, and the second light-emitting unit EU2_2 may include a second blue light-emitting layer BEML2. In other words, the second sub-middle layer SML2 may include the first blue light-emitting layer BEML1, the charge generation layer CGL, and the second blue light-emitting layer BEML2, which are sequentially stacked in the second sub-emission region SEA2 between the second pixel electrode PE2 and the common electrode CE along the third direction DR3.

The first blue light-emitting layer BEML1 may be a common layer that is positioned in common in the first and second sub-middle layers SML1 and SML2. In other words, the first and second sub-middle layers SML1 and SML2 may share the first blue light-emitting layer BEML1.

The first and second sub-middle layers SML1 and SML2 may include different numbers of light-emitting layers. For example, the number of blue light-emitting layers included in the second sub-middle layer SML2 may be greater than the number of blue light-emitting layers included in the first sub-middle layer SML1. For example, as illustrated in FIG. 10, the first sub-middle layer SML1 may include one blue light-emitting layer, i.e., the first blue light-emitting layer BEML1, and the second sub-middle layer SML2 may include two blue light-emitting layers, i.e., the first and second blue light-emitting layers BEML1 and BEML2.

The first and second sub-middle layers SML1 and SML2 may have different thicknesses. For example, a second thickness T2 of the second sub-middle layer SML2 may be greater than a first thickness T1 of the first sub-middle layer SML1. In other words, the second sub-middle layer SML2 may be thicker than the first sub-middle layer SML1 because the second sub-middle layer SML2 further includes the charge generation layer CGL and the second blue light-emitting layer BEML2, compared to the first sub-middle layer SML1.

The first and second blue light-emitting layers BEML1 and BEML2 may emit blue light.

The first blue light-emitting layer BEML1 may include an organic material layer. The organic material layer of the first blue light-emitting layer BEML1 may include a host material containing CBP or mCP and may be a phosphorescent material including a dopant material containing (4,6-F2ppy)2Irpic or L2BD111, but the present disclosure is not limited thereto.

The second blue light-emitting layer BEML2 may include an organic material layer. The organic material layer of the second blue light-emitting layer BEML2 may be the same as the organic material layer of the first blue light-emitting layer BEML1.

As the number of blue light-emitting layers included in the first sub-middle layer SML1 differs from the number of blue light-emitting layers included in the second sub-middle layer SML2, the first and second sub-middle layers SML1 and SML2 may emit blue light with different gray levels (or luminances) in accordance with the electric field between the second pixel electrode PE2 and the common electrode CE. For example, a sub-middle layer that has a relatively smaller number of light-emitting layers may emit light first in response to a voltage (e.g., a pixel voltage) applied to the second pixel electrode PE2. For example, when a pixel voltage is applied to the second pixel electrode PE2, the first sub-middle layer SML1 may emit blue light with a second gray level, and the second sub-middle layer SML2 may emit blue light with a first gray level, which is lower than the second gray level, or darker blue light. That is, a sub-middle layer that has a relatively larger number of light-emitting layers may emit blue light with a lower gray level for each given pixel voltage. Consequently, a broader range of gray levels can be presented in each pixel even at lower voltages. As a result, the range of data voltages for generating a pixel voltage can be expanded.

The second light-emitting element ED2 may have the same configuration as the first light-emitting element ED1 of any one of FIGS. 7 through 9 except that it includes blue light-emitting layers, instead of red light-emitting layers.

A fourth light-emitting element may have the same configuration as the second light-emitting element ED2.

Referring to FIG. 10, the first sub-middle layer SML1 may have a 1-tandem structure that includes one blue light-emitting layer, i.e., the first blue light-emitting layer BEML1, and the second sub-middle layer SML2 may have a 2-tandem structure that includes two blue light-emitting layers, i.e., the first and second blue light-emitting layers BEML1 and BEML2, which are disposed in the first and second light-emitting units EU2_1 and EU2_2, respectively, with one charge generation layer, i.e., the charge generation layer CGL, interposed therebetween.

FIG. 11 is a detailed cross-sectional view of a third light-emitting element of the display device of FIG. 5.

Referring to FIG. 11, a third light-emitting element ED3 may include a third pixel electrode PE3, a common electrode CE, and a third middle layer ML3.

The third middle layer ML3 may be disposed between the third pixel electrode PE3 and the common electrode CE. The third middle layer ML3 may include first and second sub-middle layers SML1 and SML2. The first sub-middle layer SML1 may be disposed in a first sub-emission region SEA1 of a third emission region EA3, and the second sub-middle layer SML2 may be disposed in a second sub-emission region SEA2 of the third emission region EA3.

The first sub-middle layer SML1 may include a first light-emitting unit EU1, which is on the third pixel electrode PE3. The first light-emitting unit EU1 may include a first green light-emitting layer GEML1. In other words, the first sub-middle layer SML1 may include the first green light-emitting layer GEML1, which is disposed in the first sub-emission region SEA1 between the third pixel electrode PE3 and the common electrode CE.

The second sub-middle layer SML2 may include a first light-emitting unit EU2_1, which is on the third pixel electrode PE3, a charge generation layer CGL, which is on the first light-emitting unit EU2_1, and a second light-emitting unit EU2_2, which is on the charge generation layer CGL. The first light-emitting unit EU2_1 may include the first green light-emitting layer GEML1, and the second light-emitting unit EU2_2 may include a second green light-emitting layer GEML2. In other words, the second sub-middle layer SML2 may include the first green light-emitting layer GEML1, the charge generation layer CGL, and the second green light-emitting layer GEML2, which are sequentially stacked in the second sub-emission region SEA2 between the third pixel electrode PE3 and the common electrode CE along the third direction DR3.

The first green light-emitting layer GEML1 may be a common layer that is positioned in common in the first and second sub-middle layers SML1 and SML2. In other words, the first and second sub-middle layers SML1 and SML2 may share the first green light-emitting layer GEML1.

The first and second sub-middle layers SML1 and SML2 may include different numbers of light-emitting layers. For example, the number of green light-emitting layers included in the second sub-middle layer SML2 may be greater than the number of green light-emitting layers included in the first sub-middle layer SML1. For example, as illustrated in FIG. 11, the first sub-middle layer SML1 may include one green light-emitting layer, i.e., the first green light-emitting layer GEML1, and the second sub-middle layer SML2 may include two green light-emitting layers, i.e., the first and second green light-emitting layers GEML1 and GEML2.

The first and second sub-middle layers SML1 and SML2 may have different thicknesses. For example, a second thickness T2 of the second sub-middle layer SML2 may be greater than a first thickness T1 of the first sub-middle layer SML1. In other words, the second sub-middle layer SML2 may be thicker than the first sub-middle layer SML1 because the second sub-middle layer SML2 further includes the charge generation layer CGL and the second green light-emitting layer GEML2, compared to the first sub-middle layer SML1.

The first and second green light-emitting layers GEML1 and GEML2 may emit green light.

The first green light-emitting layer GEML1 may include an organic material layer. The organic material layer of the first green light-emitting layer GEML1 may include a host material containing CBP or mCP and may be a phosphorescent material including a dopant material containing fac tris(2-phenylpyridine) iridium (Ir(ppy)₃), but the present disclosure is not limited thereto. Alternatively, the organic material layer of the first green light-emitting layer GEML1 may be a fluorescent material containing tris(8-hydroxyquinolino)aluminum (Alq3), but the present disclosure is not limited thereto.

The second green light-emitting layer GEML2 may include an organic material layer. The organic material layer of the second green light-emitting layer GEML2 may be the same as the organic material layer of the first green light-emitting layer GEML1.

As the number of green light-emitting layers included in the first sub-middle layer SML1 differs from the number of green light-emitting layers included in the second sub-middle layer SML2, the first and second sub-middle layers SML1 and SML2 may emit green light with different gray levels (or luminances) in accordance with the electric field between the third pixel electrode PE3 and the common electrode CE. For example, a sub-middle layer that has a relatively smaller number of light-emitting layers may emit light first in response to a voltage (e.g., a pixel voltage) applied to the third pixel electrode PE3. For example, when a pixel voltage is applied to the third pixel electrode PE3, the first sub-middle layer SML1 may emit green light with a second gray level, and the second sub-middle layer SML2 may emit green light with a first gray level, which is lower than the second gray level, or darker green light. That is, a sub-middle layer that has a relatively larger number of light-emitting layers may emit green light with a lower gray level for each given pixel voltage. Consequently, a broader range of gray levels can be presented in each pixel even at lower voltages. As a result, the range of data voltages for generating a pixel voltage can be expanded.

Referring to FIG. 11, the first sub-middle layer SML1 may have a 1-tandem structure that includes one green light-emitting layer, i.e., the first green light-emitting layer GEML1, and the second sub-middle layer SML2 may have a 2-tandem structure that includes two green light-emitting layers, i.e., the first and second green light-emitting layers GEML1 and GEML2, which are disposed in the first and second light-emitting units EU2_1 and EU2_2, respectively, with one charge generation layer, i.e., the charge generation layer CGL, interposed therebetween.

The third light-emitting element ED3 may have the same configuration as the first light-emitting element ED1 of any one of FIGS. 7 through 9 except that it includes green light-emitting layers, instead of red light-emitting layers.

In the previous embodiments, the first and second sub-middle layers SML1 and SML2 of the second middle layer ML2 may have the same thicknesses as the first and second sub-middle layers SML1 and SML2, respectively, of the first middle layer ML1. For example, the second sub-middle layer SML2 of the second middle layer ML2, which is relatively thick, may have the same thickness as the second sub-middle layer SML2 of the first middle layer ML1, which is also relatively thick. For example, the first sub-middle layer SML1 of the second middle layer ML2, which is relatively thin, may have the same thickness as the first sub-middle layer SML1 of the first middle layer ML1, which is also relatively thin.

Also, in the previous embodiments, the first and second sub-middle layers SML1 and SML2 of the second middle layer ML2 may have the same numbers of light-emitting layers as the first and second sub-middle layers SML1 and SML2, respectively, of the first middle layer ML1. For example, the second sub-middle layer SML2 of the second middle layer ML2, which is relatively thick, may include the same number of light-emitting layers as the second sub-middle layer SML2 of the first middle layer ML1, which is also relatively thick. For example, the first sub-middle layer SML1 of the second middle layer ML2, which is relatively thin, may include the same number of light-emitting layers as the first sub-middle layer SML1 of the first middle layer ML1, which is also relatively thin.

Also, in the previous embodiments, the first and second sub-middle layers SML1 and SML2 of the third middle layer ML3 and first and second sub-middle layers SML1 and SML2 of a fourth middle layer ML4 may also have the same thicknesses or heights as the first and second sub-middle layers SML1 and SML2, respectively, of the first middle layer ML1.

In the previous embodiments, a light-emitting layer that is positioned in common in different sub-middle layers of a middle layer and is formed in one body may be separated between different sub-emission regions. For example, referring to FIG. 6, the first red light-emitting layer REML1 of the first sub-middle layer SML1 and the first red light-emitting layer REML1 of the second sub-middle layer SML2 may be separated by the interface between the first and second sub-emission regions SEA1 and SEA2. In other words, the first red light-emitting layer REML1 of the first sub-middle layer SML1 and the first red light-emitting layer REML1 of the second sub-middle layer SML2, which correspond to the first and second sub-emission regions SEA1 and SEA2, respectively, may not be connected, but may be physically separated.

For example, referring to FIG. 10, the first blue light-emitting layer BEML1 of the first sub-middle layer SML1 and the first blue light-emitting layer BEML1 of the second sub-middle layer SML2 may be separated by the interface between the first and second sub-emission regions SEA1 and SEA2. In other words, the first blue light-emitting layer BEML1 of the first sub-middle layer SML1 and the first blue light-emitting layer BEML1 of the second sub-middle layer SML2, which correspond to the first and second sub-emission regions SEA1 and SEA2, respectively, may not be connected, but may be physically separated.

For example, referring to FIG. 11, the first green light-emitting layer GEML1 of the first sub-middle layer SML1 and the first green light-emitting layer GEML1 of the second sub-middle layer SML2 may be separated by the interface between the first and second sub-emission regions SEA1 and SEA2. In other words, the first green light-emitting layer GEML1 of the first sub-middle layer SML1 and the first green light-emitting layer GEML1 of the second sub-middle layer SML2, which correspond to the first and second sub-emission regions SEA1 and SEA2, respectively, may not be connected, but may be physically separated.

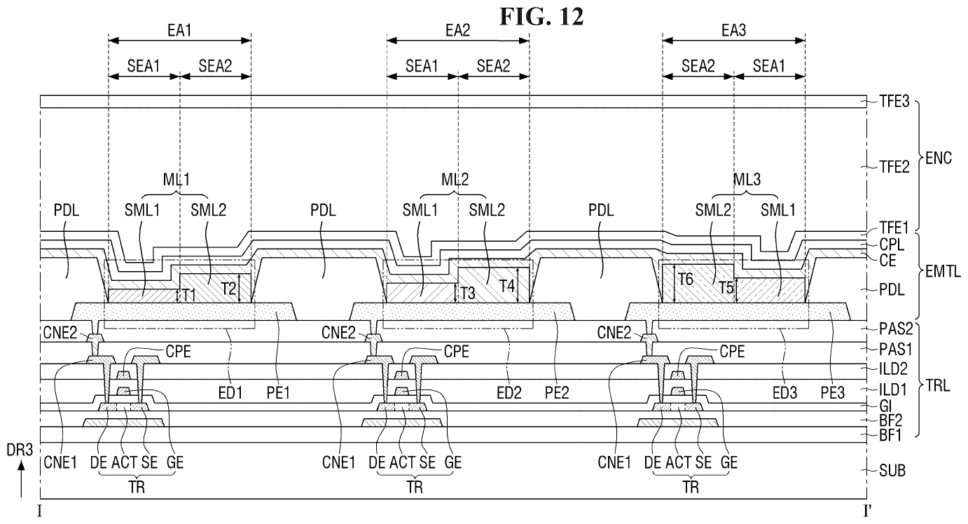

FIG. 12 is a cross-sectional view, taken along the line I-I′ of FIG. 4, of a display device according to one or more embodiments of the present disclosure.

The display device of FIG. 12 differs from the display device of FIG. 5 in that first, second, third, and fourth middle layers ML1, ML2, ML3, and ML4 have different thicknesses. In one or more embodiments, the fourth middle layer ML4 may have the same thickness as the second middle layer ML2.

Referring to FIG. 12, the middle layers of different pixels may have different thicknesses. For example, a first sub-middle layer SML1 of a first middle layer ML1 may have a different thickness from a first sub-middle layer SML1 of a second middle layer ML2, which corresponds to the first sub-middle layer SML1 of the first middle layer ML1. For example, a third thickness T3 of the first sub-middle layer SML1 of the second middle layer ML2 may be greater than a first thickness T1 of the first sub-middle layer SML1 of the first middle layer ML1. In this example, the middle layers of different pixels may include different numbers of light-emitting layers. For example, the number of light-emitting layers included in the first sub-middle layer SML1 of the first middle layer ML1 may differ from the number of light-emitting layers included in the first sub-middle layer SML1 of the second middle layer ML2. For example, the number of light-emitting layers included in the first sub-middle layer SML1 of the second middle layer ML2 may be greater than the number of light-emitting layers included in the first sub-middle layer SML1 of the first middle layer ML1.

As illustrated in FIG. 12, the first thickness T1 of the first sub-middle layer SML1 of the first middle layer ML1, a second thickness T2 of a second sub-middle layer SML2 of the first middle layer ML1, the third thickness T3 of the first sub-middle layer SML1 of the second middle layer ML2, a fourth thickness T4 of a second sub-middle layer of the second middle layer ML2, a fifth thickness T5 of a first sub-middle layer SML1 of a third middle layer ML3, a sixth thickness T6 of a second sub-middle layer SML2 of the third middle layer ML3, the thickness of a first sub-middle layer of a fourth middle layer, and the thickness of a second sub-middle layer of the fourth middle layer may all differ from one another. The first middle layer ML1 of FIG. 12 may have the same configuration as the first middle layer ML1 of FIG. 7, the second middle layer ML2 of FIG. 12 may have the same configuration as the first middle layer ML1 of FIG. 8, except that it includes green light-emitting layers, instead of red light-emitting layers, and the third middle layer ML3 of FIG. 12 may have the same configuration as the first middle layer ML1 of FIG. 9, except that it includes green light-emitting layers, instead of red light-emitting layers. The fourth middle layer of FIG. 12 may have the same configuration as the first middle layer ML1 of FIG. 8.

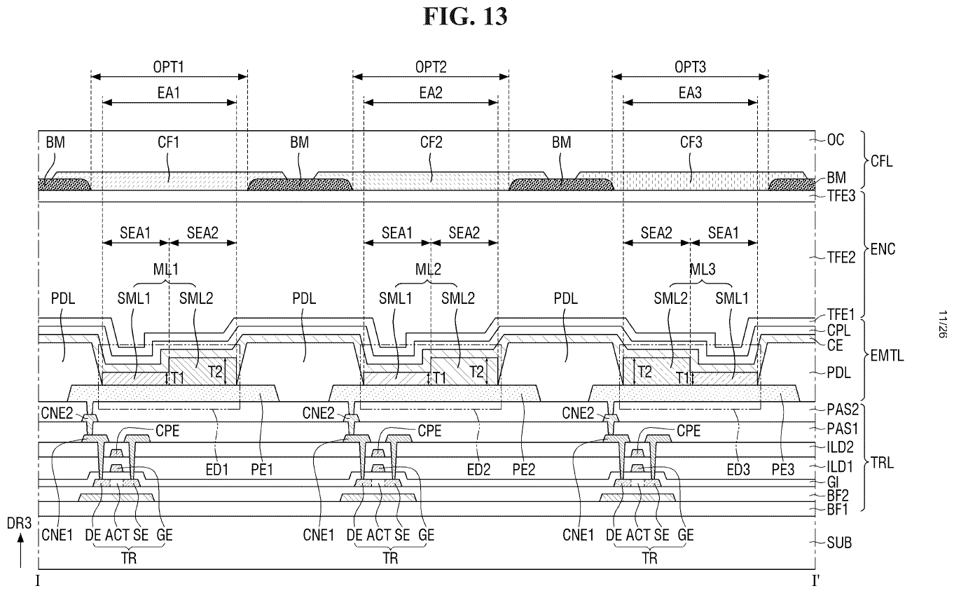

FIG. 13 is a cross-sectional view, taken along the line I-I′ of FIG. 4, of a display device according to one or more embodiments of the present disclosure.

The display device of FIG. 13 differs from the display device of FIG. 5 except that it further includes a color filter layer CFL and first, second, third, and fourth middle layers ML1, ML2, ML3, and ML4 to emit white light.

The color filter layer CFL may be disposed on an encapsulation layer ENC. For example, the color filter layer CFL may be disposed on a second encapsulation inorganic film TFE3 of the encapsulation layer ENC.

The color filter layer CFL may include, for example, a light-blocking layer BM, a plurality of color filters (CF1, CF2, and CF3), and an overcoat layer OC.

The light-blocking layer BM may be disposed on the encapsulation layer ENC. The light-blocking layer BM may include a plurality of holes (OPT1, OPT2, and OPT3), which are disposed to overlap with a plurality of emission regions (EA1, EA2, and EA3). For example, a first hole OPT1 may overlap with a first emission region EA1, a second hole OPT2 may overlap with a second emission region EA2, and a third hole OPT3 may overlap with a third emission region EA3. The area or size of the holes (OPT1, OPT2, and OPT3) may be greater than the area or size of the emission regions (EA1, EA2, and EA3) defined by a bank PDL. As the holes (OPT1, OPT2, and OPT3) of the light-blocking layer BM are formed to be larger than the emission regions (EA1, EA2, and EA3), light emitted from the emission regions (EA1, EA2, and EA3) may become visible to a user not only in front of the display device 1, but also from the sides of the display device 1.

The light-blocking layer BM may include a light-absorbing material. For example, the light-blocking layer BM may include an inorganic black pigment or an organic black pigment. The inorganic black pigment may be carbon black, and the organic black pigment may include at least one of lactam black, perylene black, and/or aniline black. However, the present disclosure is not limited to this. The light-blocking layer BM can improve color reproduction by preventing light intrusion and color mixing between the first, second, and third emission regions EA1, EA2, and EA3.

The color filters (CF1, CF2, and CF3) may be disposed to correspond to the emission regions (EA1, EA2, and EA3). For example, the color filters (CF1, CF2, and CF3) may be disposed on the light-emitting layer EMTL, which includes the holes (OPT1, OPT2, and OPT3) that correspond to the emission regions (EA1, EA2, and EA3).

The color filters (CF1, CF2, and CF3) may include first, second, and third color filters CF1, CF2, and CF3, which are disposed to correspond to different emission regions. The color filters (CF1, CF2, and CF3) may include a colorant such as a pigment or dye capable of absorbing light of wavelengths other than a particular wavelength range and may be positioned to correspond to the colors of light emitted from the emission regions (EA1, EA2, and EA3). For example, the first color filer CF1 may be positioned to overlap with the first emission region EA1 and may be a red color filter capable of transmitting only red light therethrough, the second color filter CF2 may be positioned to overlap with the second emission region EA2 and may be a blue color filter capable of transmitting only blue light therethrough, and the third color filter CF3 may be positioned to overlap with the third emission region EA3 and may be a green color filter capable of transmitting only green light therethrough.

The color filters (CF1, CF2, and CF3) may be spaced from one another on the light-blocking layer BM. The color filters (CF1, CF2, and CF3) may cover the holes (OPT1, OPT2, and OPT3). The color filters (CF1, CF2, and CF3) may have a larger area than the holes (OPT1, OPT2, and OPT3), but only to the extent that they can be sufficiently spaced from one another on the light-blocking layer BM. However, the present disclosure is not limited to this. Alternatively, the color filters (CF1, CF2, and CF3) may be positioned to partially overlap with one another. Different color filters may overlap with one another on the light-blocking layer BM, which does not overlap with the emission regions EA1, EA2, and EA3. As the color filters (CF1, CF2, and CF3) are positioned to overlap with one another, the intensity of reflected light of external light can be reduced. Furthermore, the color of reflected light of external light can be controlled by adjusting the layout, shape, and area of the color filters (CF1, CF2, and CF3).

The overcoat layer OC may be disposed on the color filters (CF1, CF2, and CF3) and may planarize the tops of the color filters (CF1, CF2, and CF3). The overcoat layer OC may be a colorless transparent layer that does not have any color in the visible wavelength range. For example, the overcoat layer OC may include a colorless transparent organic material such as an acrylic resin.

A first light-emitting element ED1 may include a first pixel electrode PE1, a common electrode CE, and a first middle layer ML1. The first middle layer ML1 may be disposed between the first pixel electrode PE1 and the common electrode CE. The first middle layer ML1 may be positioned on the first pixel electrode PE1 to overlap with the first pixel electrode PE1.

A second light-emitting element ED2 may include a second pixel electrode PE2, the common electrode CE, and a second middle layer ML2. The second middle layer ML2 may be disposed between the second pixel electrode PE2 and the common electrode CE. The second middle layer ML2 may be positioned on the second pixel electrode PE2 to overlap with the second pixel electrode PE2.

A third light-emitting element ED3 may include a third pixel electrode PE3, the common electrode CE, and a third middle layer ML3. The third middle layer ML3 may be disposed between the third pixel electrode PE3 and the common electrode CE. The third middle layer ML3 may be positioned on the third pixel electrode PE3 to overlap with the third pixel electrode PE3.

The first, second, and third middle layers ML1, ML2, and ML3 may emit white light. For example, the first middle layer ML1 may have a tandem structure where a plurality of light-emitting units that provide different colors of light are stacked in a vertical direction (e.g., a third direction DR3). For example, the second and third middle layers ML2 and ML3 may also have a tandem structure where a plurality of light-emitting units that provide different colors of light are stacked in the vertical direction (e.g., the third direction DR3).

As illustrated in FIG. 13, a middle layer positioned in one emission region may have different thicknesses. For example, a middle layer positioned on one pixel electrode may have different thicknesses in an emission region that overlaps with the pixel electrode. For example, the first middle layer ML1, which overlaps with (or is in contact with) the first pixel electrode PE1 and is disposed in the first emission region EA1, may have different thicknesses, i.e., first and second thicknesses T1 and T2, in the first emission region EA1 (e.g., T2>T1).

For example, the second middle layer ML2, which overlaps with (or is in contact with) the second pixel electrode PE2 and is disposed in the second emission region EA2, may have different thicknesses, i.e., first and second thicknesses T1 and T2, in the second emission region EA2 (e.g., T2>T1).

For example, the third middle layer ML3, which overlaps with (or is in contact with) the third pixel electrode PE3 and is disposed in the third emission region EA3, may have different thicknesses, i.e., first and second thicknesses T1 and T2, in the third emission region EA3 (e.g., T2>T1).

Here, the thickness of each middle layer refers to the dimension measured in the third direction DR3.

Each of the first, second, and third middle layers ML1, ML2, and ML3 may include a plurality of sub-middle layers. For example, as illustrated in FIG. 13, the first middle layer ML1 may include first and second sub-middle layers SML1 and SML2, which are disposed in first and second sub-emission regions SEA1 and SEA2, respectively, of the first emission region EA1. The second thickness T2 of the second sub-middle layer SML2 of the first middle layer ML1 may be greater than the first thickness T1 of the first sub-middle layer SML1 of the first middle layer ML1 (i.e., T2>T1).

For example, as illustrated in FIG. 13, the second middle layer ML2 may include first and second sub-middle layers SML1 and SML2, which are disposed in first and second sub-emission regions SEA1 and SEA2, respectively, of the second emission region EA2. The second thickness of the second sub-middle layer SML2 of the second middle layer ML2 may be greater than the first thickness T1 of the first sub-middle layer SML1 of the second middle layer ML2 (i.e., T2>T1).

For example, as illustrated in FIG. 13, the third middle layer ML3 may include first and second sub-middle layers SML1 and SML2, which are disposed in first and second sub-emission regions SEA1 and SEA2, respectively, of the third emission region EA3. The second thickness T2 of the second sub-middle layer SML2 of the third middle layer ML3 may be greater than the first thickness T1 of the first sub-middle layer SML1 of the third middle layer ML3 (i.e., T2>T1).

Here, the thickness of each sub-middle layer refers to the dimension of each sub-middle layer, measured in the third direction DR3.

In one or more embodiments, the bank PDL may further include a fourth emission region EA4, which exposes a fourth pixel electrode PE4, the light-blocking layer BM may further include a fourth hole, which is disposed to overlap with the fourth emission region EA4, and the color filter layer CFL may further include a second color filter CF2, which is disposed to overlap with the fourth emission region EA4 and transmits only blue light therethrough.

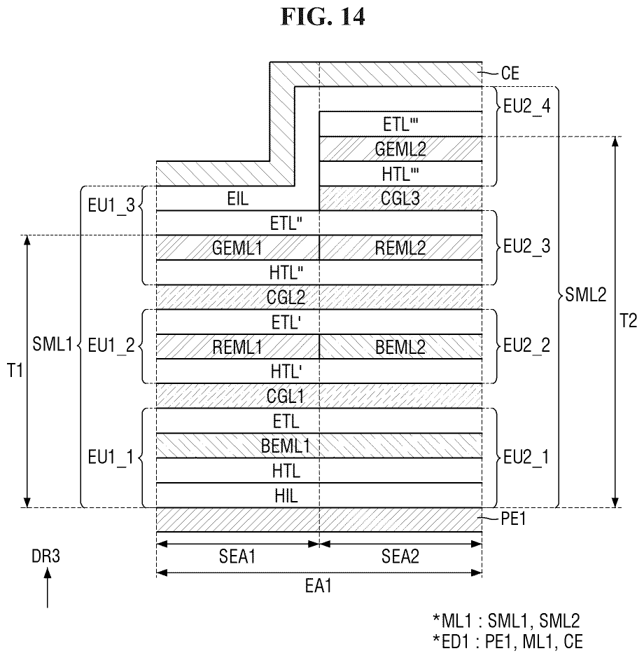

FIG. 14 is a cross-sectional view of a first light-emitting element of the display device of FIG. 13.

Referring to FIG. 14, a first light-emitting element ED1 may include a first pixel electrode PE1, a common electrode CE, and a first middle layer ML1.

The first middle layer ML1 may be disposed between the first pixel electrode PE1 and the common electrode CE. The first middle layer ML1 may include first and second sub-middle layers SML1 and SML2. The first sub-middle layer SML1 may be disposed in a first sub-emission region SEA1 of a first emission region EA1, and the second sub-middle layer SML2 may be disposed in a second sub-emission region SEA2 of the first emission region EA1.

The first sub-middle layer SML1 may include a first light-emitting unit EU1_1, which is on the first pixel electrode PE1, a first charge generation layer CGL1, which is on the first light-emitting unit EU1_1, a second light-emitting unit EU1_2, which is on the first charge generation layer CGL1, a second charge generation layer CGL2, which is on the second light-emitting unit EU1_2, and a third light-emitting unit EU1_3, which is on the second charge generation layer CGL2.

The first light-emitting unit EU1_1 may include a hole injection layer HIL, a hole transport layer HTL, a first blue light-emitting layer BEML1, and an electron transport layer ETL, which are sequentially stacked on the first pixel electrode PE1 along the third direction DR3. The first charge generation layer CGL1 may be disposed on the electron transport layer ETL. The second light-emitting unit EU1_2 may include a hole transport layer HTL′, a first red light-emitting layer REML1, and an electron transport layer ETL′, which are sequentially stacked on the first charge generation layer CGL1 along the third direction DR3. The second charge generation layer CGL2 may be disposed on the electron transport layer ETL′. The third light-emitting unit EU1_3 may include a hole transport layer HTL″, a first green light-emitting layer GEML1, an electron transport layer ETL″, and an electron injection layer EIL, which are sequentially stacked on the second charge generation layer CGL2 along the third direction DR3. In other words, the first sub-middle layer SML1 may include the hole injection layer HIL, the hole transport layer HTL, the first blue light-emitting layer BEML1, the electron transport layer ETL, the first charge generation layer CGL1, the hole transport layer HTL′, the first red light-emitting layer REML1, the electron transport layer ETL′, the second charge generation layer CGL2, the hole transport layer HTL″, the first green light-emitting layer GEML1, the electron transport layer ETL″, and the electron injection layer EIL, which are sequentially stacked in the first sub-emission region SEA1 between the first pixel electrode PE1 and the common electrode along the third direction DR3.

The second sub-middle layer SML2 may include a first light-emitting unit EU2_1, which is on the first pixel electrode PE1, the first charge generation layer CGL1, which is disposed on the first light-emitting unit EU2_1, a second light-emitting unit EU2_2, which is on the first charge generation layer CGL1, the second charge generation layer CGL2, which is on the second light-emitting unit EU2_2, a third light-emitting unit EU2_3, which is disposed on the second charge generation layer CGL2, a third charge generation layer CGL3, which is on the third light-emitting unit EU2_3, and a fourth light-emitting unit EU2_4, which is on the third charge generation layer CGL3.

The first light-emitting unit EU2_1 may include the hole injection layer HIL, the hole transport layer HTL, the first blue light-emitting layer BEML1, and the electron transport layer ETL, which are sequentially stacked on the first pixel electrode PE1 along the third direction DR3. The first charge generation layer CGL1 may be disposed on the electron transport layer ETL. The second light-emitting unit EU2_2 may include the hole transport layer HTL′, the second blue light-emitting layer BEML2, and the electron transport layer ETL′, which are sequentially stacked on the first charge generation layer CGL1 along the third direction DR3. The second charge generation layer CGL2 may be disposed on the electron transport layer ETL′. The third light-emitting unit EU2_3 may include the hole transport layer HTL″, a second red light-emitting layer REML2, and the electron transport layer ETL″, which are sequentially stacked on the second charge generation layer CGL2 along the third direction DR3. The third charge generation layer CGL3 may be disposed on the electron transport layer ETL″. The fourth light-emitting unit EU2_4 may be disposed on the third charge generation layer CGL3 and may include a hole transport layer HTL″, a second green light-emitting layer GEML2, an electron transport layer ETL″, and the electron injection layer EIL, which are sequentially stacked on the third charge generation layer CGL3 along the third direction DR3. In other words, the second sub-middle layer SML2 may include the hole injection layer HIL, the hole transport layer HTL, the first blue light-emitting layer BEML1, the electron transport layer ETL, the first charge generation layer CGL1, the hole transport layer HTL′, the second blue light-emitting layer BEML2, the electron transport layer ETL′, the second charge generation layer CGL2, the hole transport layer HTL″, the second red light-emitting layer REML2, the electron transport layer ETL″, third charge generation layer CGL3, the hole transport layer HTL″, the second green light-emitting layer GEML2, the electron transport layer ETL″, and the electron injection layer EIL, which are sequentially stacked in the second sub-emission region SEA2 between the first pixel electrode PE1 and the common electrode CE along the third direction DR3.

The hole injection layer HIL, the hole transport layer HTL, the first blue light-emitting layer BEML1, the electron transport layer ETL, the first charge generation layer CGL1, the hole transport layer HTL′, the electron transport layer ETL′, the second charge generation layer CGL2, the hole transport layer HTL″, the electron transport layer ETL″, and the electron injection layer EIL may be common layers that are positioned in common in the first and second sub-middle layers SML1 and SML2. In other words, the first and second sub-middle layers SML1 and SML2 may share the hole injection layer HIL, the hole transport layer HTL, the first blue light-emitting layer BEML1, the electron transport layer ETL, the first charge generation layer CGL1, the hole transport layer HTL′, the electron transport layer ETL′, the second charge generation layer CGL2, the hole transport layer HTL″, the electron transport layer ETL″, and the electron injection layer EIL.

The first and second blue light-emitting layers BEML1 and BEML2 may emit blue light, the first and second red light-emitting layers REML1 and REML2 may emit red light, and the first and second green light-emitting layers GEML1 and GEML2 may emit green light.

The first and second sub-middle layers SML1 and SML2 may have different numbers of light-emitting layers. For example, the number of light-emitting layers included in the second sub-middle layer SML2 may be greater than the number of light-emitting layers included in the first sub-middle layer SML1. For example, as illustrated in FIG. 14, the first sub-middle layer SML1 may include three light-emitting layers, i.e., the first blue light-emitting layer BEML1, the first red light-emitting layer REML1, and the first green light-emitting layer GEML1, whereas the second sub-middle layer SML2 may include four light-emitting layers, i.e., the first blue light-emitting layer BEML1, the second blue light-emitting layer BEML2, the second red light-emitting layer REML2, and the second green light-emitting layer GEML2.

The first and second sub-middle layers SML1 and SML2 may have different thicknesses. For example, a second thickness T2 of the second sub-middle layer SML2 may be greater than a first thickness T1 of the first sub-middle layer SML1. For example, when the distance from the bottom surface of the first middle layer ML1 to the top surface of the uppermost light-emitting layer (i.e., the first green light-emitting layer GEML1) of the first sub-middle layer SML1 is defined as the first thickness T1 and the distance from the bottom surface of the first middle layer ML1 to the top surface of the uppermost light-emitting layer (i.e., the second green light-emitting layer GEML2) of the second sub-middle layer SML2 is defined as the second thickness T2, the second thickness T2 may be greater than the first thickness T1.

Referring to FIG. 14, the first sub-middle layer SML1 may have a 3-tandem structure that includes three light-emitting layers, i.e., the first blue light-emitting layer BEML1, the first red light-emitting layer REML1, and the first green light-emitting layer GEML1, which are disposed in the first, second, and third light-emitting units EU1_1, EU1_2, and EU1_3, respectively, with two charge generation layers, i.e., the first and second charge generation layers CGL1 and CGL2, interposed therebetween, and the second sub-middle layer SML2 may have a 4-tandem structure that includes four light-emitting layers, i.e., the first blue light-emitting layer BEML1, the second blue light-emitting layer BEML2, the second red light-emitting layer REML2, and the second green light-emitting layer GEML2, which are disposed in the first, second, third, and fourth light-emitting units EU2_1, EU2_2, EU2_3, and EU2_4, respectively, with three charge generation layers, i.e., the first, second, and third charge generation layers CGL1, CGL2, and CGL3, interposed therebetween.

As the number of light-emitting layers included in the first sub-middle layer SML1 differs from the number of light-emitting layers included in the second sub-middle layer SML2, the first and second sub-middle layers SML1 and SML2 may emit white light with different gray levels (or luminances) in accordance with the electric field between the first pixel electrode PE1 and the common electrode CE. For example, a sub-middle layer that has a relatively smaller number of light-emitting layers may emit light first in response to a voltage (e.g., a pixel voltage) applied to the first pixel electrode PE1. For example, when a pixel voltage is applied to the first pixel electrode PE1, the first sub-middle layer SML1 may emit white light with a second gray level, and the second sub-middle layer SML2 may emit white light with a first gray level, which is lower than the second gray level, or darker white light. That is, a sub-middle layer that has a relatively larger number of light-emitting layers may emit white light with a lower gray level for each given pixel voltage. Consequently, a broader range of gray levels can be presented in each pixel even at lower voltages. As a result, the range of data voltages for generating a pixel voltage can be expanded.

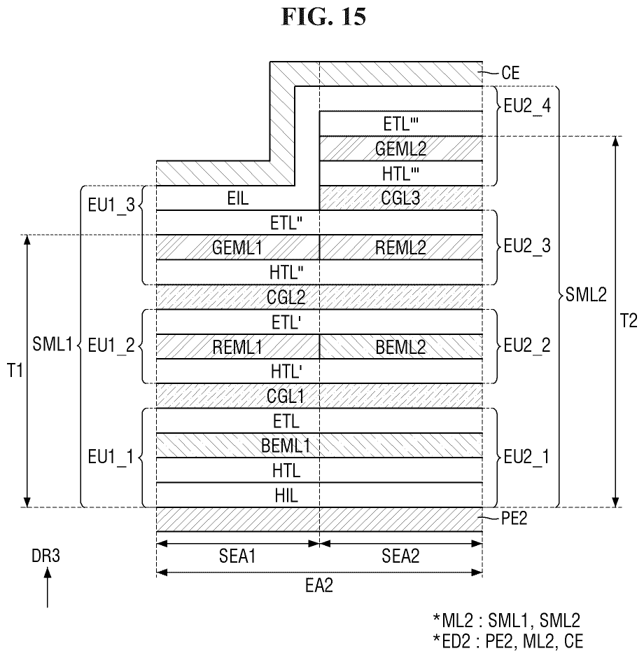

FIG. 15 is a detailed cross-sectional view of a second light-emitting element of the display device of FIG. 13.

Referring to FIG. 15, a second light-emitting element ED2 may include a second pixel electrode PE2, a common electrode CE, and a second middle layer ML2.

The second middle layer ML2 may be disposed between the second pixel electrode PE2 and the common electrode CE. The second middle layer ML2 may include first and second sub-middle layers SML1 and SML2. The first sub-middle layer SML1 may be disposed in a first sub-emission region SEA1 of a second emission region EA2, and the second sub-middle layer SML2 may be disposed in a second sub-emission region SEA2 of the second emission region EA2.

The first sub-middle layer SML1 may include a first light-emitting unit EU1_1, which is on the second pixel electrode PE2, a first charge generation layer CGL1, which is on the first light-emitting unit EU1_1, a second light-emitting unit EU1_2, which is on the first charge generation layer CGL1, a second charge generation layer CGL2, which is on the second light-emitting unit EU1_2, and a third light-emitting unit EU1_3, which is on the second charge generation layer CGL2.

The first light-emitting unit EU1_1 may include a hole injection layer HIL, a hole transport layer HTL, a first blue light-emitting layer BEML1, and an electron transport layer ETL, which are sequentially stacked on the second pixel electrode PE2 along the third direction DR3. The first charge generation layer CGL1 may be disposed on the electron transport layer ETL. The second light-emitting unit EU1_2 may include a hole transport layer HTL′, a first red light-emitting layer REML1, and an electron transport layer ETL′, which are sequentially stacked on the first charge generation layer CGL1 along the third direction DR3. The second charge generation layer CGL2 may be disposed on the electron transport layer ETL′. The third light-emitting unit EU1_3 may include a hole transport layer HTL″, a first green light-emitting layer GEML1, an electron transport layer ETL″, and an electron injection layer EIL, which are sequentially stacked on the second charge generation layer CGL2 along the third direction DR3. In other words, the first sub-middle layer SML1 may include the hole injection layer HIL, the hole transport layer HTL, the first blue light-emitting layer BEML1, the electron transport layer ETL, the first charge generation layer CGL1, the hole transport layer HTL′, the first red light-emitting layer REML1, the electron transport layer ETL′, the second charge generation layer CGL2, the hole transport layer HTL″, the first green light-emitting layer GEML1, the electron transport layer ETL″, and the electron injection layer EIL, which are sequentially stacked in the first sub-emission region SEA1 between the second pixel electrode PE2 and the common electrode CE along the third direction DR3.

The second sub-middle layer SML2 may include a first light-emitting unit EU2_1, which is on the second pixel electrode PE2, the first charge generation layer CGL1, which is on the first light-emitting unit EU2_1, a second light-emitting unit EU2_2, which is on the first charge generation layer CGL1, the second charge generation layer CGL2, which is on the second light-emitting unit EU2_2, a third light-emitting unit EU2_3, which is disposed on the second charge generation layer CGL2, a third charge generation layer CGL3, which is on the third light-emitting unit EU2_3, and a fourth light-emitting unit EU2_4, which is on the third charge generation layer CGL3.

The first light-emitting unit EU2_1 may include the hole injection layer HIL, the hole transport layer HTL, the first blue light-emitting layer BEML1, and the electron transport layer ETL, which are sequentially stacked on the second pixel electrode PE2 along the third direction DR3. The first charge generation layer CGL1 may be disposed on the electron transport layer ETL. The second light-emitting unit EU2_2 may include the hole transport layer HTL′, the second blue light-emitting layer BEML2, and the electron transport layer ETL′, which are sequentially stacked on the first charge generation layer CGL1 along the third direction DR3. The second charge generation layer CGL2 may be disposed on the electron transport layer ETL′. The third light-emitting unit EU2_3 may include the hole transport layer HTL″, the second red light-emitting layer REML2, and the electron transport layer ETL″, which are sequentially stacked on the second charge generation layer CGL2 along the third direction DR3. The third charge generation layer CGL3 may be disposed on the electron transport layer ETL″. The fourth light-emitting unit EU2_4 may include a hole transport layer HTL″, a second green light-emitting layer GEML2, an electron transport layer ETL″, and the electron injection layer EIL, which are sequentially stacked on the third charge generation layer CGL3 along the third direction DR3. In other words, the second sub-middle layer SML2 may include the hole injection layer HIL, the hole transport layer HTL, the first blue light-emitting layer BEML1, the electron transport layer ETL, the first charge generation layer CGL1, the hole transport layer HTL′, the second blue light-emitting layer BEML2, the electron transport layer ETL′, the second charge generation layer CGL2, the hole transport layer HTL″, the second red light-emitting layer REML2, the electron transport layer ETL″, the third charge generation layer CGL3, the hole transport layer HTL″, the second green light-emitting layer GEML2, the electron transport layer ETL″, and the electron injection layer EIL, which are sequentially stacked in the second sub-emission region SEA2 between the second pixel electrode PE2 and the common electrode CE along the third direction DR3.

The hole injection layer HIL, the hole transport layer HTL, the first blue light-emitting layer BEML1, the electron transport layer ETL, the first charge generation layer CGL1, the hole transport layer HTL′, the electron transport layer ETL′, the second charge generation layer CGL2, the hole transport layer HTL″, the electron transport layer ETL″, and the electron injection layer EIL may be common layers that are positioned in common in the first and second sub-middle layers SML1 and SML2. In other words, the first and second sub-middle layers SML1 and SML2 may share the hole injection layer HIL, the hole transport layer HTL, the first blue light-emitting layer BEML1, the electron transport layer ETL, the first charge generation layer CGL1, the hole transport layer HTL′, the electron transport layer ETL′, the second charge generation layer CGL2, the hole transport layer HTL″, the electron transport layer ETL″, and the electron injection layer EIL.

The first and second blue light-emitting layers BEML1 and BEML2 may emit blue light, the first and second red light-emitting layers REML1 and REML2 may emit red light, and the first and second green light-emitting layers GEML1 and GEML2 may emit green light.

The first and second sub-middle layers SML1 and SML2 may include different numbers of light-emitting layers. For example, the number of light-emitting layers included in the second sub-middle layer SML2 may be greater than the number of light-emitting layers included in the first sub-middle layer SML1. For example, as illustrated in FIG. 15, the first sub-middle layer SML1 may include three light-emitting layers (i.e., the first blue light-emitting layer BEML1, the first red light-emitting layer REML1, and the first green light-emitting layer GEML1), whereas the second sub-middle layer SML2 may include four light-emitting layers, i.e., the first blue light-emitting layer BEML1, the second blue light-emitting layer BEML2, the second red light-emitting layer REML2, and the second green light-emitting layer GEML2.

The first and second sub-middle layers SML1 and SML2 may have different thicknesses. For example, a second thickness T2 of the second sub-middle layer SML2 may be greater than a first thickness T1 of the first sub-middle layer SML1. For example, when the distance from the bottom surface of the second middle layer ML2 to the top surface of the uppermost light-emitting layer (i.e., the first green light-emitting layer GEML1) of the first sub-middle layer SML1 is defined as the first thickness T1 and the distance from the bottom surface of the second middle layer ML2 to the top surface of the uppermost light-emitting layer (i.e., the second green light-emitting layer GEML2) of the second sub-middle layer SML2 is defined as the second thickness T2, the second thickness T2 may be greater than the first thickness T1.

Referring to FIG. 15, the first sub-middle layer SML1 may have a 3-tandem structure that includes three light-emitting layers, i.e., the first blue light-emitting layer BEML1, the first red light-emitting layer REML1, and the first green light-emitting layer GEML1, which are disposed in the first, second, and third light-emitting units EU1_1, EU1_2, and EU1_3, respectively, with two charge generation layers, i.e., the first and second charge generation layers CGL1 and CGL2, interposed therebetween, and the second sub-middle layer SML2 may have a 4-tandem structure that includes four light-emitting layers, i.e., the first blue light-emitting layer BEML1, the second blue light-emitting layer BEML2, the second red light-emitting layer REML2, and the second green light-emitting layer GEML2, which are disposed in the first, second, third, and fourth light-emitting units EU2_1, EU2_2, EU2_3, and EU2_4, respectively, with three charge generation layers, i.e., the first, second, and third charge generation layers CGL1, CGL2, and CGL3, interposed therebetween.

As the number of light-emitting layers included in the first sub-middle layer SML1 differs from the number of light-emitting layers included in the second sub-middle layer SML2, the first and second sub-middle layers SML1 and SML2 may emit white light with different gray levels (or luminances) in accordance with the electric field between the second pixel electrode PE2 and the common electrode CE. For example, a sub-middle layer that has a relatively smaller number of light-emitting layers may emit light first in response to a voltage (e.g., a pixel voltage) applied to the second pixel electrode PE2. For example, when a pixel voltage is applied to the second pixel electrode PE2, the first sub-middle layer SML1 may emit white light with a second gray level, and the second sub-middle layer SML2 may emit white light with a first gray level, which is lower than the second gray level, or darker white light. That is, a sub-middle layer that has a relatively larger number of light-emitting layers may emit white light with a lower gray level for each given pixel voltage. Consequently, a broader range of gray levels can be presented in each pixel even at lower voltages. As a result, the range of data voltages for generating a pixel voltage can be expanded.

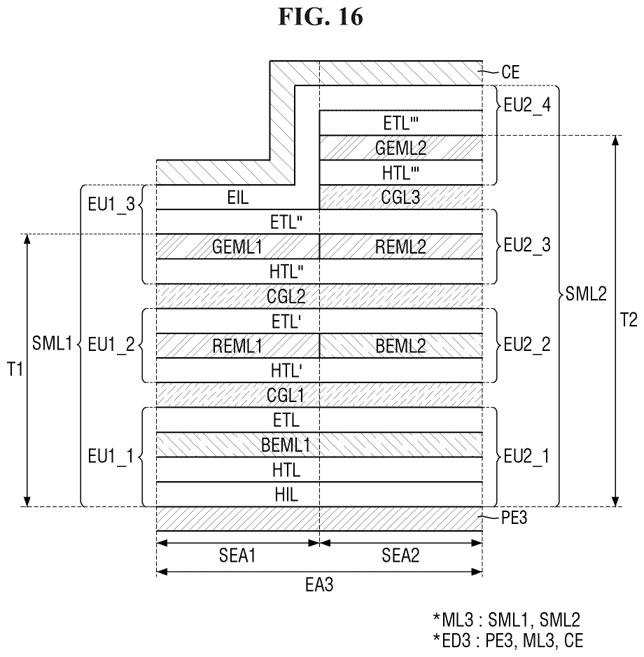

FIG. 16 is a detailed cross-sectional view of a third light-emitting element of the display device of FIG. 13.

Referring to FIG. 16, a third light-emitting element ED3 may include a third pixel electrode PE3, a common electrode CE, and a third middle layer ML3.

The third middle layer ML3 may be disposed between the third pixel electrode PE3 and the common electrode CE. The third middle layer ML3 may include first and second sub-middle layers SML1 and SML2. The first sub-middle layer SML1 may be disposed in a first sub-emission region SEA1 of a third emission region EA3, and the second sub-middle layer SML2 may be disposed in a second sub-emission region SEA2 of the third emission region EA3.

The first sub-middle layer SML1 may include a first light-emitting unit EU1_1, which is on the third pixel electrode PE3, a first charge generation layer CGL1, which is on the first light-emitting unit EU1_1, a second light-emitting unit EU1_2, which is on the first charge generation layer CGL1, a second charge generation layer CGL2, which is on the second light-emitting unit EU1_2, and a third light-emitting unit EU1_3, which is on the second charge generation layer CGL2.

The first light-emitting unit EU1_1 may include a hole injection layer HIL, a hole transport layer HTL, a first blue light-emitting layer BEML1, and an electron transport layer ETL, which are sequentially stacked on the third pixel electrode PE3 along the third direction DR3. The first charge generation layer CGL1 may be disposed on the electron transport layer ETL. The second light-emitting unit EU1_2 may include a hole transport layer HTL′, a first red light-emitting layer REML1, and an electron transport layer ETL′, which are sequentially stacked on the first charge generation layer CGL1 along the third direction DR3. The second charge generation layer CGL2 may be disposed on the electron transport layer ETL′. The third light-emitting unit EU1_3 may include a hole transport layer HTL″, a first green light-emitting layer GEML1, an electron transport layer ETL″, and an electron injection layer EIL, which are sequentially stacked on the second charge generation layer CGL2 along the third direction DR3. In other words, the first sub-middle layer SML1 may include the hole injection layer HIL, the hole transport layer HTL, the first blue light-emitting layer BEML1, the electron transport layer ETL, the first charge generation layer CGL1, the hole transport layer HTL′, the first red light-emitting layer REML1, the electron transport layer ETL′, the second charge generation layer CGL2, the hole transport layer HTL″, the first green light-emitting layer GEML1, the electron transport layer ETL″, and the electron injection layer EIL, which are sequentially stacked in the first sub-emission region SEA1 between the third pixel electrode PE3 and the common electrode along the third direction DR3.

The second sub-middle layer SML2 may include a first light-emitting unit EU2_1, which is on the third pixel electrode PE3, the first charge generation layer CGL1, which is on the first light-emitting unit EU2_1, a second light-emitting unit EU2_2, which is on the first charge generation layer CGL1, the second charge generation layer CGL2, which is on the second light-emitting unit EU2_2, a third light-emitting unit EU2_3, which is disposed on the second charge generation layer CGL2, a third charge generation layer CGL3, which is on the third light-emitting unit EU2_3, and a fourth light-emitting unit EU2_4, which is on the third charge generation layer CGL3.

The first light-emitting unit EU2_1 may include the hole injection layer HIL, the hole transport layer HTL, the first blue light-emitting layer BEML1, and the electron transport layer ETL, which are sequentially stacked on the third pixel electrode PE3 along the third direction DR3. The first charge generation layer CGL1 may be disposed on the electron transport layer ETL. The second light-emitting unit EU2_2 may include the hole transport layer HTL′, the second blue light-emitting layer BEML2, and the electron transport layer ETL′, which are sequentially stacked on the first charge generation layer CGL1 along the third direction DR3. The second charge generation layer CGL2 may be disposed on the electron transport layer ETL′. The third light-emitting unit EU2_3 may include the hole transport layer HTL″, the second red light-emitting layer REML2, and the electron transport layer ETL″, which are sequentially stacked on the second charge generation layer CGL2 along the third direction DR3. The fourth light-emitting unit EU2_4 may include a hole transport layer HTL″, a second green light-emitting layer GEML2, an electron transport layer ETL″, and the electron injection layer EIL, which are sequentially stacked on the third charge generation layer CGL3 along the third direction DR3. In other words, the second sub-middle layer SML2 may include the hole injection layer HIL, the hole transport layer HTL, the first blue light-emitting layer BEML1, the electron transport layer ETL, the first charge generation layer CGL1, the hole transport layer HTL′, the second blue light-emitting layer BEML2, the electron transport layer ETL′, the second charge generation layer CGL2, the hole transport layer HTL″, the second red light-emitting layer REML2, the electron transport layer ETL″, the third charge generation layer CGL3, the hole transport layer HTL″, the second green light-emitting layer GEML2, the electron transport layer ETL″, and the electron injection layer EIL, which are sequentially stacked in the second sub-emission region SEA2 between the third pixel electrode PE3 and the common electrode CE along the third direction DR3.

The hole injection layer HIL, the hole transport layer HTL, the first blue light-emitting layer BEML1, the electron transport layer ETL, the first charge generation layer CGL1, the hole transport layer HTL′, the electron transport layer ETL′, the second charge generation layer CGL2, the hole transport layer HTL″, the electron transport layer ETL″, and the electron injection layer EIL may be common layers that are positioned in common in the first and second sub-middle layers SML1 and SML2. In other words, the first and second sub-middle layers SML1 and SML2 may share the hole injection layer HIL, the hole transport layer HTL, the first blue light-emitting layer BEML1, the electron transport layer ETL, the first charge generation layer CGL1, the hole transport layer HTL′, the electron transport layer ETL′, the second charge generation layer CGL2, the hole transport layer HTL″, the electron transport layer ETL″, and the electron injection layer EIL.

The first and second blue light-emitting layers BEML1 and BEML2 may emit blue light, the first and second red light-emitting layers REML1 and REML2 may emit red light, and the first and second green light-emitting layers GEML1 and GEML2 may emit green light.

The first and second sub-middle layers SML1 and SML2 may include different numbers of light-emitting layers. For example, the number of light-emitting layers included in the second sub-middle layer SML2 may be greater than the number of light-emitting layers included in the first sub-middle layer SML1. For example, as illustrated in FIG. 16, the first sub-middle layer SML1 may include three light-emitting layers (i.e., the first blue light-emitting layer BEML1, the first red light-emitting layer REML1, and the first green light-emitting layer GEML1), whereas the second sub-middle layer SML2 may include four light-emitting layers, i.e., the first blue light-emitting layer BEML1, the second blue light-emitting layer BEML2, the second red light-emitting layer REML2, and the second green light-emitting layer GEML2.

The first and second sub-middle layers SML1 and SML2 may have different thicknesses. For example, a second thickness T2 of the second sub-middle layer SML2 may be greater than a first thickness T1 of the first sub-middle layer SML1. For example, when the distance from the bottom surface of the third middle layer ML3 to the top surface of the uppermost light-emitting layer (i.e., the first green light-emitting layer GEML1) of the first sub-middle layer SML1 is defined as the first thickness T1 and the distance from the bottom surface of the third middle layer ML3 to the top surface of the uppermost light-emitting layer (i.e., the second green light-emitting layer GEML2) of the second sub-middle layer SML2 is defined as the second thickness T2, the second thickness T2 may be greater than the first thickness T1.

Referring to FIG. 16, the first sub-middle layer SML1 may have a 3-tandem structure that includes three light-emitting layers, i.e., the first blue light-emitting layer BEML1, the first red light-emitting layer REML1, and the first green light-emitting layer GEML1, which are disposed in the first, second, and third light-emitting units EU1_1, EU1_2, and EU1_3, respectively, with two charge generation layers, i.e., the first and second charge generation layers CGL1 and CGL2, interposed therebetween, and the second sub-middle layer SML2 may have a 4-tandem structure that includes four light-emitting layers, i.e., the first blue light-emitting layer BEML1, the second blue light-emitting layer BEML2, the second red light-emitting layer REML2, and the second green light-emitting layer GEML2, which are disposed in the first, second, third, and fourth light-emitting units EU2_1, EU2_2, EU2_3, and EU2_4, respectively, with three charge generation layers, i.e., the first, second, and third charge generation layers CGL1, CGL2, and CGL3, interposed therebetween.

As the number of light-emitting layers included in the first sub-middle layer SML1 differs from the number of light-emitting layers included in the second sub-middle layer SML2, the first and second sub-middle layers SML1 and SML2 may emit white light with different gray levels (or luminances) in accordance with the electric field between the third pixel electrode PE3 and the common electrode CE. For example, a sub-middle layer that has a relatively smaller number of light-emitting layers may emit light first in response to a voltage (e.g., a pixel voltage) applied to the third pixel electrode PE3. For example, when a pixel voltage is applied to the third pixel electrode PE3, the first sub-middle layer SML1 may emit white light with a second gray level, and the second sub-middle layer SML2 may emit white light with a first gray level, which is lower than the second gray level, or darker white light. That is, a sub-middle layer that has a relatively larger number of light-emitting layers may emit white light with a lower gray level for each given pixel voltage. Consequently, a broader range of gray levels can be presented in each pixel even at lower voltages. As a result, the range of data voltages for generating a pixel voltage can be expanded.

In the embodiment of FIG. 13, the thicknesses of the first, second, and third middle layers ML1, ML2, and ML3 may differ from one another. In other words, the thicknesses of the first, second, and third middle layers ML1, ML2, and ML3 may differ from those depicted in FIG. 12.

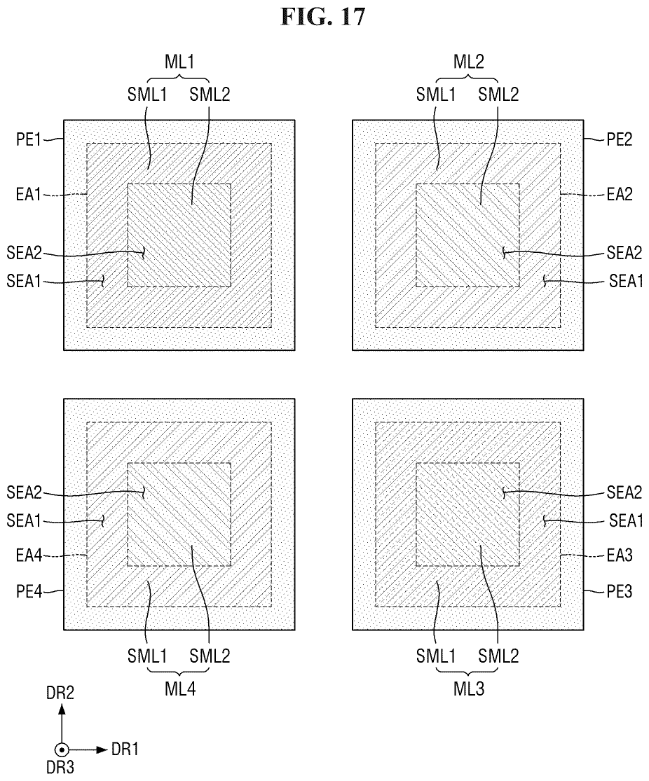

FIG. 17 is a plan view of multiple pixels of a display device according to one or more embodiments of the present disclosure.

The display device of FIG. 17 differs from the display device of FIG. 4 in the shape of middle layers and will hereinafter be described, highlighting the differences with the display device 1 of FIG. 4.

Referring to FIG. 17, a first middle layer ML1, which is disposed in a first emission region EA1 between a first pixel electrode PE1 and a common electrode CE, may include first and second sub-middle layers SML1 and SML2.

The first sub-middle layer SML1 of the first middle layer ML1 may be disposed in a first sub-emission region SEA1 of the first emission region EA1, and the second sub-middle layer SML2 of the first middle layer ML1 may be disposed in a second sub-emission region SEA2 of the first emission region EA1. As already mentioned above, the second sub-middle layer SML2 of the first middle layer ML1 may have a greater thickness than the first sub-middle layer SML1 of the first middle layer ML1. Further, as already mentioned above, the second sub-middle layer SML2 of the first middle layer ML1 may include a larger number of light-emitting layers the first sub-middle layer SML1 of the first middle layer ML1. In a plan view, the first sub-middle layer SML1 of the first middle layer ML1 may be around (e.g., may surround) the second sub-middle layer SML2 of the first middle layer ML1. For example, in a plan view, the second sub-middle layer SML2 of the first middle layer ML1 may have a rectangular shape, and the first sub-middle layer SML1 of the first middle layer ML1 may have a rectangular ring shape surrounding the second sub-middle layer SML2 of the first middle layer ML1.

A second middle layer ML2, which is disposed in a second emission region EA2 between a second pixel electrode PE2 and the common electrode CE, may have the same configuration as the first middle layer ML1. In other words, first and second sub-middle layers SML1 and SML2 of the second middle layer ML2 may have the same configuration as the first and second sub-middle layers SML1 and SML2 of the first middle layer ML1.

A third middle layer ML3, which is disposed in a third emission region EA3 between a third pixel electrode PE3 and the common electrode CE, may have the same configuration as the first middle layer ML1. In other words, first and second sub-middle layers SML1 and SML2 of the third middle layer ML3 may have the same configuration as the first and second sub-middle layers SML1 and SML2 of the first middle layer ML1.

A fourth middle layer ML4, which is disposed in a fourth emission region EA4 between a fourth pixel electrode PE4 and the common electrode CE, may have the same configuration as the first middle layer ML1. In other words, first and second sub-middle layers SML1 and SML2 of the fourth middle layer ML4 may have the same configuration as the first and second sub-middle layers SML1 and SML2 of the first middle layer ML1. In one or more embodiments, the fourth middle layer ML4 may have the same configuration as the second middle layer ML2. The fourth middle layer ML4 may emit the same color of light as the second middle layer ML2.

The first middle layer ML1 may emit red light, the second and fourth middle layers ML2 and ML4 may emit blue light, and the third middle layer ML3 may emit green light.

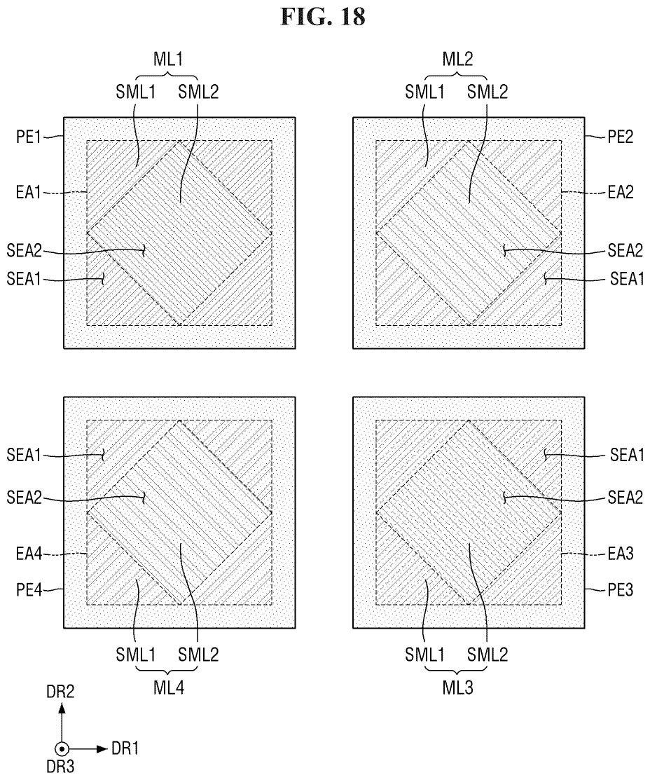

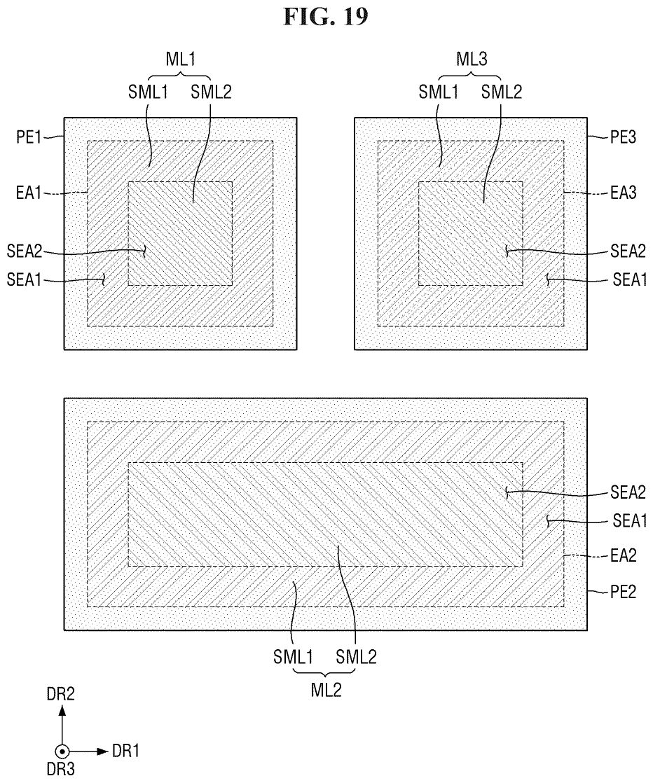

FIG. 18 is a plan view of multiple pixels of a display device according to one or more embodiments of the present disclosure.

The display device of FIG. 18 differs from the display device of FIG. 4 in the shape of middle layers and will hereinafter be described, highlighting the differences with the display device of FIG. 4.

Referring to FIG. 18, a first middle layer ML1, which is disposed in a first emission region EA1 between a first pixel electrode PE1 and a common electrode CE, may include first and second sub-middle layers SML1 and SML2.

The first sub-middle layer SML1 of the first middle layer ML1 may be disposed in a first sub-emission region SEA1 of the first emission region EA1, and the second sub-middle layer SML2 of the first middle layer ML1 may be disposed in a second sub-emission region SEA2 of the first emission region EA1. As already mentioned above, the second sub-middle layer SML2 of the first middle layer ML1 may have a greater thickness than the first sub-middle layer SML1 of the first middle layer ML1. Further, as already mentioned above, the second sub-middle layer SML2 of the first middle layer ML1 may include a larger number of light-emitting layers than the first sub-middle layer SML1 of the first middle layer ML1. In a plan view, the first sub-middle layer SML1 of the first middle layer ML1 may be around (e.g., may surround) the second sub-middle layer SML2 of the first middle layer ML1. For example, in a plan view, the second sub-middle layer SML2 of the first middle layer ML1 may have a rhombus shape, and the first sub-middle layer SML1 of the first middle layer ML1 may have a rectangular ring shape surrounding the second sub-middle layer SML2 of the first middle layer ML1. Here, the four apexes of the second sub-middle layer SML2 of the first middle layer ML1 may be positioned to face the four sides of the first sub-middle layer SML1 of the first middle layer ML1. The four apexes of the second sub-middle layer SML2 of the first middle layer ML1 may be in contact with the four sides of the first sub-middle layer SML1 of the first middle layer ML1. Consequently, the first sub-middle layer SML1 of the first middle layer ML1 may be divided into four sections having a triangular shape.

A second middle layer ML2, which is disposed in a second emission region EA2 between a second pixel electrode PE2 and the common electrode CE, may have the same configuration as the first middle layer ML1. In other words, first and second sub-middle layers SML1 and SML2 of the second middle layer ML2 may have the same configuration as the first and second sub-middle layers SML1 and SML2 of the first middle layer ML1.

A third middle layer ML3, which is disposed in a third emission region EA3 between a third pixel electrode PE3 and the common electrode CE, may have the same configuration as the first middle layer ML1. In other words, first and second sub-middle layers SML1 and SML2 of the third middle layer ML3 may have the same configuration as the first and second sub-middle layers SML1 and SML2 of the first middle layer ML1.

A fourth middle layer ML4, which is disposed in a fourth emission region EA4 between a fourth pixel electrode PE4 and the common electrode CE, may have the same configuration as the first middle layer ML1. In other words, first and second sub-middle layers SML1 and SML2 of the fourth middle layer ML4 may have the same configuration as the first and second sub-middle layers SML1 and SML2 of the first middle layer ML1. Meanwhile, the fourth middle layer ML4 may have the same configuration as the second middle layer ML2. The fourth middle layer ML4 may emit the same color of light as the second middle layer ML2.

The first middle layer ML1 may emit red light, the second and fourth middle layers ML2 and ML4 may emit blue light, and the third middle layer ML3 may emit green light.

FIG. 19 is a plan view of multiple pixels of a display device according to one or more embodiments of the present disclosure.

The display device of FIG. 19 differs from the display device of FIG. 4 in the shape of middle layers and will hereinafter be described, highlighting the differences with the display device of FIG. 4.

Referring to FIG. 19, a first middle layer ML1, which is disposed in a first emission region EA1 between a first pixel electrode PE1 and a common electrode CE, may include first and second sub-middle layers SML1 and SML2.

The first sub-middle layer SML1 of the first middle layer ML1 may be disposed in a first sub-emission region SEA1 of the first emission region EA1, and the second sub-middle layer SML2 of the first middle layer ML1 may be disposed in a second sub-emission region SEA2 of the first emission region EA1. As already mentioned above, the second sub-middle layer SML2 of the first middle layer ML1 may have a greater thickness than the first sub-middle layer SML1 of the first middle layer ML1. Further, as already mentioned above, the second sub-middle layer SML2 of the first middle layer ML1 may include a larger number of light-emitting layers than the first sub-middle layer SML1 of the first middle layer ML1. In a plan view, the first sub-middle layer SML1 of the first middle layer ML1 may be around (e.g., may surround) the second sub-middle layer SML2 of the first middle layer ML1. For example, in a plan view, the second sub-middle layer SML2 of the first middle layer ML1 may have a rectangular shape, and the first sub-middle layer SML1 of the first middle layer ML1 may have a rectangular ring shape surrounding the second sub-middle layer SML2 of the first middle layer ML1.

A second middle layer ML2, which is disposed in a second emission region EA2 between a second pixel electrode PE2 and the common electrode CE, may have the same configuration as the first middle layer ML1. In other words, first and second sub-middle layers SML1 and SML2 of the second middle layer ML2 may have the same configuration as the first and second sub-middle layers SML1 and SML2 of the first middle layer ML1. However, the second middle layer ML2 may have a larger size than the first middle layer ML1.

A third middle layer ML3, which is disposed in a third emission region EA3 between a third pixel electrode PE3 and the common electrode CE, may have the same configuration as the first middle layer ML1. In other words, first and second sub-middle layers SML1 and SML2 of the third middle layer ML3 may have the same configuration as the first and second sub-middle layers SML1 and SML2 of the first middle layer ML1. The third middle layer ML3 may have the same area as the first middle layer ML1.

The first middle layer ML1 may emit red light, the second middle layer ML2 may emit blue light, and the third middle layer ML3 may emit green light.

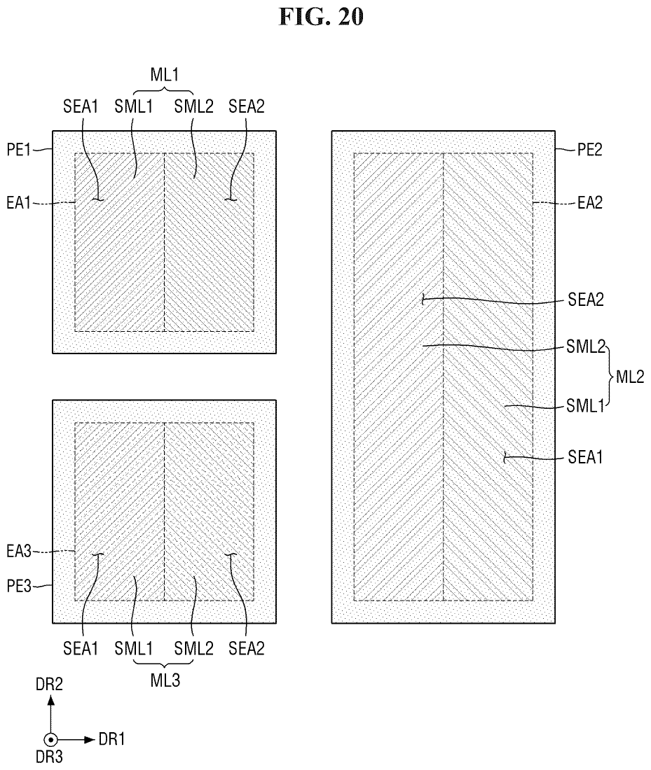

FIG. 20 is a plan view of multiple pixels of a display device according to one or more embodiments of the present disclosure.

The display device of FIG. 20 differs from the display device of FIG. 4 in the shape of middle layers and will hereinafter be described, highlighting the differences with the display device of FIG. 4.

Referring to FIG. 20, a first middle layer ML1, which is disposed in a first emission region EA1 between a first pixel electrode PE1 and a common electrode CE, may include first and second sub-middle layers SML1 and SML2.

The first sub-middle layer SML1 of the first middle layer ML1 may be disposed in a first sub-emission region SEA1 of the first emission region EA1, and the second sub-middle layer SML2 of the first middle layer ML1 may be disposed in a second sub-emission region SEA2 of the first emission region EA1. As already mentioned above, the second sub-middle layer SML2 of the first middle layer ML1 may have a greater thickness than the first sub-middle layer SML1 of the first middle layer ML1. Further, as already mentioned above, the second sub-middle layer SML2 of the first middle layer ML1 may include a larger number of light-emitting layers than the first sub-middle layer SML1 of the first middle layer ML1. In a plan view, the first and second sub-middle layers SML1 and SML2 of the first middle layer ML1 may have a rectangular shape that extends longer in a second direction DR2 than in a first direction DR1. The first and second sub-middle layers SML1 and SML2 of the first middle layer ML1 may be positioned to face each other in the first direction DR1.

A second middle layer ML2, which is disposed in a second emission region EA2 between a second pixel electrode PE2 and the common electrode CE, may include first and second sub-middle layers SML1 and SML2. The first sub-middle layer SML1 of the second middle layer ML2 may be disposed in a first sub-emission region SEA1 of the second emission region EA2, and the second sub-middle layer SML2 of the second middle layer ML2 may be disposed in a second sub-emission region SEA2 of the second emission region EA2. As already mentioned above, the second sub-middle layer SML2 of the second middle layer ML2 may have a greater thickness than the first sub-middle layer SML1 of the second middle layer ML2. Further, as already mentioned above, the second sub-middle layer SML2 of the second middle layer ML2 may include a larger number of light-emitting layers the first sub-middle layer SML1 of the second middle layer ML2. In a plan view, the first and second sub-middle layers SML1 and SML2 of the second middle layer ML2 may have a rectangular shape that extends longer in the second direction DR2 than in the first direction DR1. The first and second sub-middle layers SML1 and SML2 of the second middle layer ML2 may have a larger size than the first and second sub-middle layers SML1 and SML2 of the first middle layer ML1.

A third middle layer ML3, which is disposed in a third emission region EA3 between a third pixel electrode PE3 and the common electrode CE, may have the same configuration as the first middle layer ML1. In other words, first and second sub-middle layers SML1 and SML2 of the third middle layer ML3 may have the same configuration as the first and second sub-middle layers SML1 and SML2 of the first middle layer ML1.

The second sub-middle layers SML2 of the first, second, and third middle layers ML1, ML2, and ML3 may be positioned adjacent to one another. In other words, in each unit pixel, the second sub-middle layers SML2 of the first, second, and third middle layers ML1, ML2, and ML3 that are relatively thick may be positioned adjacent to one another.

The first middle layer ML1 may emit red light, the second middle layer ML2 may emit blue light, and the third middle layer ML3 may emit green light.

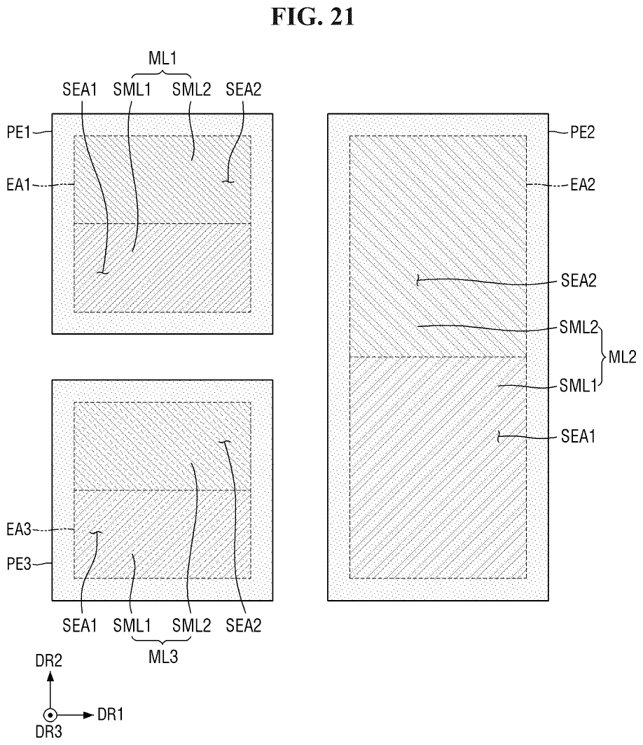

FIG. 21 is a plan view of multiple pixels of a display device according to one or more embodiments of the present disclosure.

The display device of FIG. 21 differs from the display device of FIG. 4 in the shape of middle layers and will hereinafter be described, highlighting the differences with the display device of FIG. 4.

Referring to FIG. 21, a first middle layer ML1, which is disposed in a first emission region EA1 between a first pixel electrode PE1 and a common electrode CE, may include first and second sub-middle layers SML1 and SML2.

The first sub-middle layer SML1 of the first middle layer ML1 may be disposed in a first sub-emission region SEA1 of the first emission region EA1, and the second sub-middle layer SML2 of the first middle layer ML1 may be disposed in a second sub-emission region SEA2 of the first emission region EA1. As already mentioned above, the second sub-middle layer SML2 of the first middle layer ML1 may have a greater thickness than the first sub-middle layer SML1 of the first middle layer ML1. Further, as already mentioned above, the second sub-middle layer SML2 of the first middle layer ML1 may include a larger number of light-emitting layers than the first sub-middle layer SML1 of the first middle layer ML1. In a plan view, the first and second sub-middle layers SML1 and SML2 of the first middle layer ML1 may have a rectangular shape that extends longer in a first direction DR1 than in a second direction DR2. The first and second sub-middle layers SML1 and SML2 of the first middle layer ML1 may be positioned to face each other in the second direction DR2.

A second middle layer ML2, which is disposed in a second emission region EA2 between a second pixel electrode PE2 and the common electrode CE, may include first and second sub-middle layers SML1 and SML2.

The first sub-middle layer SML1 of the second middle layer ML2 may be disposed in a first sub-emission region SEA1 of the second emission region EA2, and the second sub-middle layer SML2 of the second middle layer ML2 may be disposed in a second sub-emission region SEA2 of the second emission region EA2. As already mentioned above, the second sub-middle layer SML2 of the second middle layer ML2 may have a greater thickness than the first sub-middle layer SML1 of the second middle layer ML2. Further, as already mentioned above, the second sub-middle layer SML2 of the second middle layer ML2 may include a larger number of light-emitting layers than the first sub-middle layer SML1 of the second middle layer ML2. In a plan view, the first and second sub-middle layers SML1 and SML2 of the second middle layer ML2 may have a rectangular shape that extends longer in the second direction DR2 than in the first direction DR1.

A third middle layer ML3, which is disposed in a third emission region EA3 between a third pixel electrode PE3 and the common electrode CE, may have the same configuration as the first middle layer ML1. In other words, first and second sub-middle layers SML1 and SML2 of the third middle layer ML3 may have the same configuration as the first and second sub-middle layers SML1 and SML2 of the first middle layer ML1.

The first middle layer ML1 may emit red light, the second middle layer ML2 may emit blue light, and the third middle layer ML3 may emit green light.

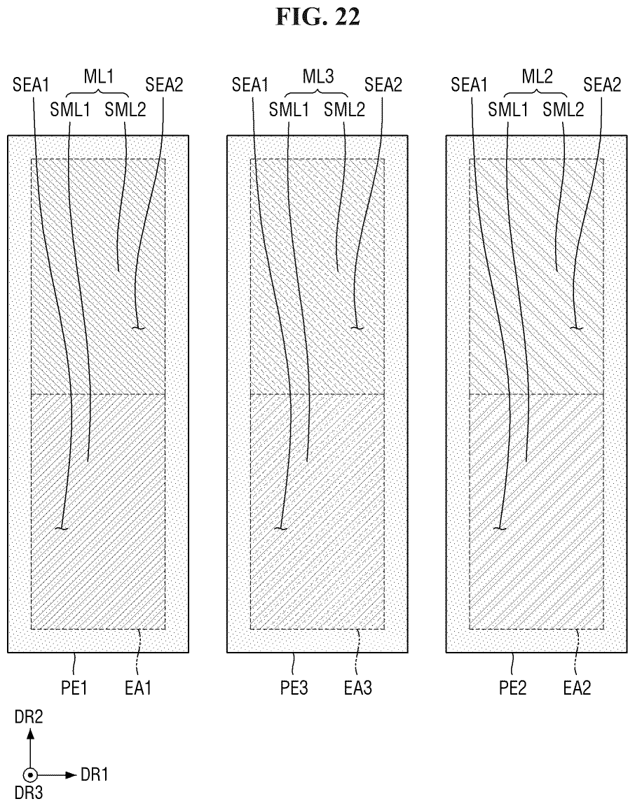

FIG. 22 is a plan view of multiple pixels of a display device according to one or more embodiments of the present disclosure.

The display device of FIG. 22 differs from the display device of FIG. 4 in the shape of middle layers and will hereinafter be described, highlighting the differences with the display device of FIG. 4.

Referring to FIG. 22, a first middle layer ML1, which is disposed in a first emission region EA1 between a first pixel electrode PE1 and a common electrode CE, may include first and second sub-middle layers SML1 and SML2.

The first sub-middle layer SML1 of the first middle layer ML1 may be disposed in a first sub-emission region SEA1 of the first emission region EA1, and the second sub-middle layer SML2 of the first middle layer ML1 may be disposed in a second sub-emission region SEA2 of the first emission region EA1. As already mentioned above, the second sub-middle layer SML2 of the first middle layer ML1 may have a greater thickness than the first sub-middle layer SML1 of the first middle layer ML1. Further, as already mentioned above, the second sub-middle layer SML2 of the first middle layer ML1 may include a larger number of light-emitting layers the first sub-middle layer SML1 of the first middle layer ML1. In a plan view, the first and second sub-middle layers SML1 and SML2 of the first middle layer ML1 may have a rectangular shape that extends longer in a second direction DR2 than in a first direction DR1. The first and second sub-middle layers SML1 and SML2 of the first middle layer ML1 may be positioned to face each other in the second direction DR2.

A second middle layer ML2, which is disposed in a second emission region EA2 between a second pixel electrode PE2 and the common electrode CE, may have the same configuration as the first middle layer ML1. In other words, first and second sub-middle layers SML1 and SML2 of the second middle layer ML2 may have the same configuration as the first and second sub-middle layers SML1 and SML2 of the first middle layer ML1.

A third middle layer ML3, which is disposed in a third emission region EA3 between a third pixel electrode PE3 and the common electrode CE, may have the same configuration as the first middle layer ML1. In other words, first and second sub-middle layers SML1 and SML2 of the third middle layer ML3 may have the same configuration as the first and second sub-middle layers SML1 and SML2 of the first middle layer ML1. The third middle layer ML3 may be disposed between the first and second middle layers ML1 and ML2. The first, second, and third middle layers ML1, ML2, and ML3 may be arranged in a row in the first direction DR1.

The first middle layer ML1 may emit red light, the second middle layer ML2 may emit blue light, and the third middle layer ML3 may emit green light.

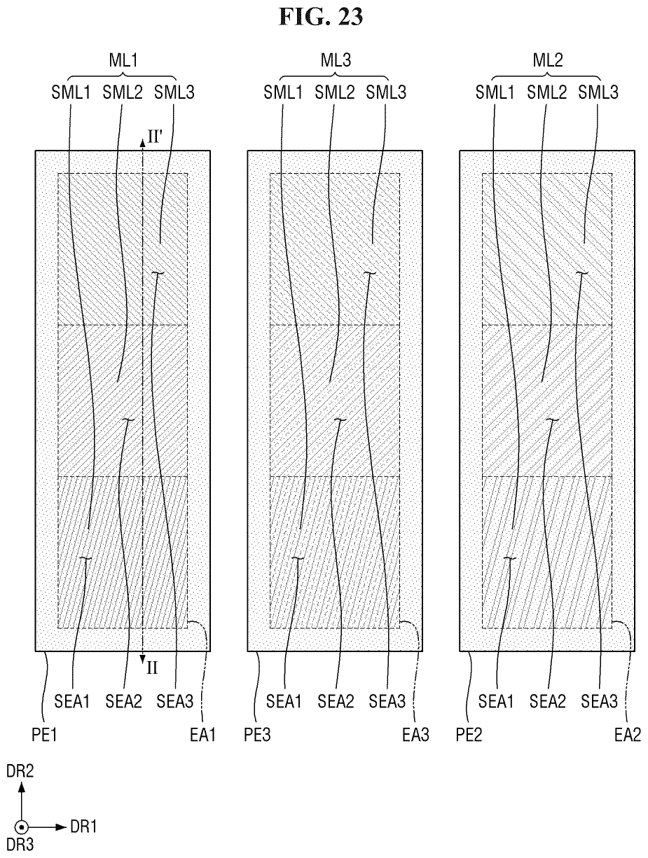

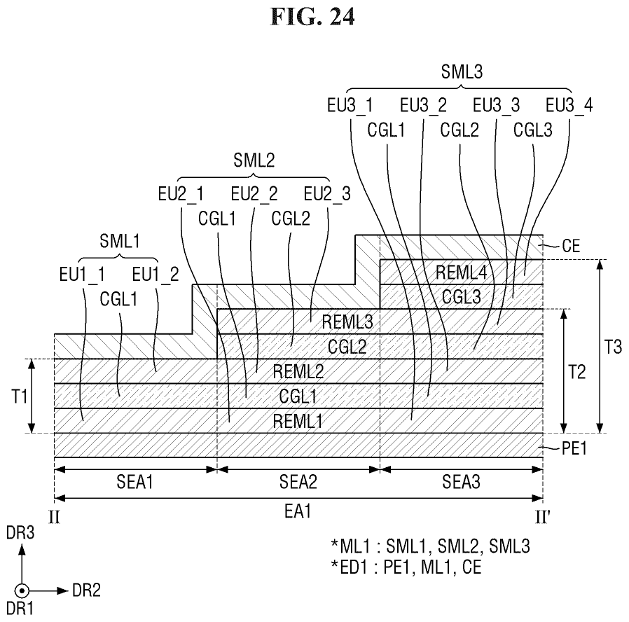

FIG. 23 is a plan view of multiple pixels of a display device according to one or more embodiments of the present disclosure, and FIG. 24 is a cross-sectional view taken along the line II-II′ of FIG. 23.

Referring to FIGS. 23 and 24, a first middle layer ML1, which is disposed in a first emission region EA1 between a first pixel electrode PE1 and a common electrode CE, may include first, second, and third sub-middle layers SML1, SML2, and SML3.

The first, second, and third sub-middle layers SML1, SML2, and SML3 of the first middle layer ML1 may be arranged in a row in a second direction DR2. The second sub-middle layer SML2 of the first middle layer ML1 may be disposed between the first and third sub-middle layers SML1 and SML3 of the first middle layer ML1.

The first middle layer ML1 may be disposed in first, second, and third sub-emission regions SEA1, SEA2, and SEA3, respectively, of the first emission region EA1.

As illustrated in FIG. 24, the first sub-middle layer SML1 of the first middle layer ML1 may include a first light-emitting unit EU1_1, a first charge generation layer CGL1, and a second light-emitting unit EU1_2, which are sequentially stacked on the first pixel electrode PE1 along a third direction DR3. The second sub-middle layer SML2 of the first middle layer ML1 may include a first light-emitting unit EU2_1, the first charge generation layer CGL1, a second light-emitting unit EU2_2, a second charge generation layer CGL2, and a third light-emitting unit EU2_3, which are sequentially stacked on the first pixel electrode PE1 along the third direction DR3. The third sub-middle layer SML3 of the first middle layer ML1 may include a first light-emitting unit EU3_1, the first charge generation layer CGL1, a second light-emitting unit EU3_2, the second charge generation layer CGL2, a third light-emitting unit EU3_3, a third charge generation layer CGL3, and a fourth light-emitting unit EU3_4, which are sequentially stacked on the first pixel electrode PE1 along the third direction DR3.

As illustrated in FIG. 24, the first and second light-emitting units EU1_1 and EU1_2 of the first sub-middle layer SML1 of the first middle layer ML1 may include first and second red light-emitting layers REML1 and REML2, respectively, and the first, second, and third light-emitting units EU2_1, EU2_2, and EU2_3 of the second sub-middle layer SML2 of the first middle layer ML1 may include the first red light-emitting layer REML1, the second red light-emitting layer REML2, and a third red light-emitting layer REML3, respectively, and the first, second, third, and fourth light-emitting units EU3_1, EU3_2, EU3_3, and EU3_4 of the third sub-middle layer SML3 of the first middle layer ML1 may include the first red light-emitting layer REML1, the second red light-emitting layer REML2, the third red light-emitting layer REML3, and a fourth red light-emitting layer REML4, respectively.

In a plan view, the first, second, and third sub-middle layers SML1, SML2, and SML3 of the first middle layer ML1 may have a rectangular shape that extends longer in the second direction DR2 than in a first direction DR1. The first and second sub-middle layers SML1 and SML2 of the first middle layer ML1 may be positioned to face each other in the second direction DR2, and the second and third sub-middle layers SML2 and SML3 of the first middle layer ML1 may be positioned to face each other in the second direction DR2.

The first, second, and third sub-middle layers SML1, SML2, and SML3 of the first middle layer ML1 may have different thicknesses. For example, as illustrated in FIG. 23, a second thickness T2 of the second sub-middle layer SML2 of the first middle layer ML1 may be greater than a first thickness T1 of the first sub-middle layer SML1 of the first middle layer ML1, and a third thickness T3 of the third sub-middle layer SML3 of the first middle layer ML1 may be greater than the second thickness T2 of the second sub-middle layer SML2 of the first middle layer ML1 (i.e., T1<T2<T3).

The first, second, and third sub-middle layers SML1, SML2, and SML3 of the first middle layer ML1 may include different numbers of light-emitting layers. For example, as illustrated in FIG. 23, the second sub-middle layer SML2 of the first middle layer ML1 may include a larger number of light-emitting layers (e.g., red light-emitting layers) than the first sub-middle layer SML1 of the first middle layer ML1, and the third sub-middle layer SML3 of the first middle layer ML1 may include a larger number of light-emitting layers (e.g., red light-emitting layers) than the second sub-middle layer SML2 of the first middle layer ML1. FIG. 24 illustrates that the first sub-middle layer SML1 of the first middle layer ML1 includes two red light-emitting layers, i.e., the first and second red light-emitting layers REML1 and REML2, the second sub-middle layer SML2 of the first middle layer ML1 includes three red light-emitting layers, i.e., the first, second, and third red light-emitting layers REML1, REML2, and REML3, and the third sub-middle layer SML3 of the first middle layer ML1 includes four red light-emitting layers, i.e., the first, second, third, and fourth red light-emitting layers REML1, REML2, REML3, and REML4.

A second middle layer ML2, which is disposed in a second emission region EA2 between a second pixel electrode PE2 and the common electrode CE, may include first, second, and third sub-middle layers SML1, SML2, and SML3.

The first, second, and third sub-middle layers SML1, SML2, and SML3 of the second middle layer ML2 may be arranged in a row in the second direction DR2. The second sub-middle layer SML2 of the second middle layer ML2 may be disposed between the first and third sub-middle layers SML1 and SML3 of the second middle layer ML2.

The first, second, and third sub-middle layers SML1, SML2, and SML3 of the second middle layer ML2 may be disposed in first, second, and third sub-emission regions SEA1, SEA2, and SEA3, respectively, of the second emission region EA2.

In a plan view, the first, second, and third sub-middle layers SML1, SML2, and SML3 of the second middle layer ML2 may have a rectangular shape that extends longer in the second direction DR2 than in the first direction DR1. The first and second sub-middle layers SML1 and SML2 of the second middle layer ML2 may be positioned to face each other in the second direction DR2, and the second and third sub-middle layers SML2 and SML3 of the second middle layer ML2 may be positioned to face each other in the second direction DR2.

The second middle layer ML2 may have different thicknesses. For example, a second thickness T2 of the second sub-middle layer SML2 of the second middle layer ML2 may be greater than a first thickness T1 of the first sub-middle layer SML1 of the second middle layer ML2, and a third thickness T3 of the third sub-middle layer SML3 of the second middle layer ML2 may be greater than the second thickness T2 of the second sub-middle layer SML2 of the second middle layer ML2 (i.e., T1<T2<T3).

The first, second, and third sub-middle layers SML1, SML2, and SML3 of the second middle layer ML2 may include different numbers of light-emitting layers. For example, the second sub-middle layer SML2 of the second middle layer ML2 may include a larger number of light-emitting layers (e.g., blue light-emitting layers) than the first sub-middle layer SML1 of the second middle layer ML2, and the third sub-middle layer SML3 of the second middle layer ML2 may include a larger number of light-emitting layers (e.g., blue light-emitting layers) than the second sub-middle layer SML2 of the second middle layer ML2.

A third middle layer ML3, which is disposed in a third emission region EA3 between a third pixel electrode PE3 and the common electrode CE, may include first, second, and third sub-middle layers SML1, SML2, and SML3.

The first, second, and third sub-middle layers SML1, SML2, and SML3 of the third middle layer ML3 may be arranged in a row in the second direction DR2. The second sub-middle layer SML2 of the third middle layer ML3 may be disposed between the first and third sub-middle layers SML1 and SML3 of the third middle layer ML3.

The third middle layer ML3 may be disposed in first, second, and third sub-emission regions SEA1, SEA2, and SEA3, respectively, of the third emission region EA3.

In a plan view, the first, second, and third sub-middle layers SML1, SML2, and SML3 of the third middle layer ML3 may have a rectangular shape that extends longer in the second direction DR2 than in the first direction DR1. The first and second sub-middle layers SML1 and SML2 of the third middle layer ML3 may be positioned to face each other in the second direction DR2, and the second and third sub-middle layers SML2 and SML3 of the third middle layer ML3 may be positioned to face each other in the second direction DR2.

The first, second, and third sub-middle layers SML1, SML2, and SML3 of the third middle layer ML3 may have different thicknesses. For example, the thickness of the second sub-middle layer SML2 of the third middle layer ML3 may be greater than the thickness of the first sub-middle layer SML1 of the third middle layer ML3, and the thickness of the third sub-middle layer SML3 of the third middle layer ML3 may be greater than the thickness of the second sub-middle layer SML2 of the third middle layer ML3.

The first, second, and third sub-middle layers SML1, SML2, and SML3 of the third middle layer ML3 may include different numbers of light-emitting layers. For example, the second sub-middle layer SML2 of the third middle layer ML3 may include a larger number of light-emitting layers (e.g., green light-emitting layers) than the first sub-middle layer SML1 of the third middle layer ML3, and the third sub-middle layer SML3 of the third middle layer ML3 may include a larger number of light-emitting layers (e.g., green light-emitting layers) than the second sub-middle layer SML2 of the third middle layer ML3.

In each unit pixel, the third middle layer ML3 may be disposed between the first and second middle layers ML1 and ML2.

The first middle layer ML1 may emit red light, the second middle layer ML2 may emit blue light, and the third middle layer ML3 may emit green light.

Referring to FIGS. 23 and 24, the first sub-middle layer SML1 of the first middle layer ML1 may have a 2-tandem structure that includes two red light-emitting layers, i.e., the first and second red light-emitting layers REML1 and REML2, which are disposed in the first and second light-emitting units EU1_1 and EU1_2, respectively, with one charge generation layer, i.e., the first charge generation layer CGL1, interposed therebetween, the second sub-middle layer SML2 of the first middle layer ML1 may have a 3-tandem structure that includes three red light-emitting layers, i.e., the first, second, and third red light-emitting layers REML1, REML2, and REML3, which are disposed in the first, second, and third light-emitting units EU2_1, EU2_2, and EU2_3, respectively, with two charge generation layers, i.e., the first and second charge generation layers CGL1 and CGL2, interposed therebetween, and the third sub-middle layer SML3 may have a 4-tandem structure that includes four red light-emitting layers, i.e., the first, second, third, and fourth red light-emitting layers REML1, REML2, REML3, and REML4, which are disposed in the first, second, third, and fourth light-emitting units EU3_1, EU3_2, EU3_3, and EU3_4, respectively, with three charge generation layers, i.e., the first, second, and third charge generation layers CGL1, CGL2, and CGL3, interposed therebetween.

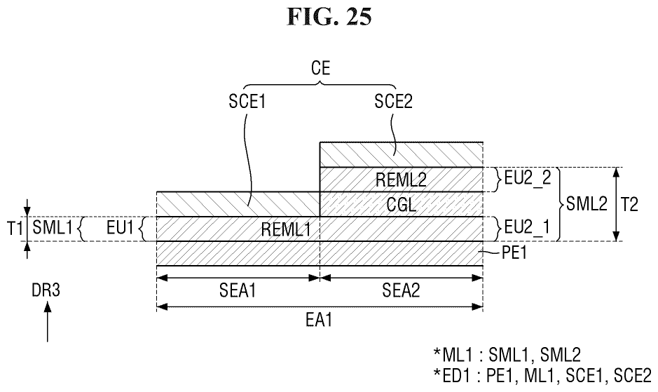

FIG. 25 is a cross-sectional view of a first light-emitting element of a display device according to one or more embodiments of the present disclosure.

Referring to FIG. 25, a common electrode CE of a first light-emitting element ED1 may be divided into sections that correspond to different sub-middle layers. The first light-emitting element ED1 may include a first pixel electrode PE1, a first middle layer ML1, and first and second sub-common electrodes (or first and second sub-electrodes) SCE1 and SCE2. The first and second sub-common electrodes SCE1 and SCE2 may be physically and/or electrically separated from each other, and different common voltages may be applied to the first and second sub-common electrodes SCE1 and SCE2. For example, a first common voltage may be applied to the first sub-common electrode SCE1, and a second common electrode, which is different from the first common electrode, may be applied to the second sub-common electrode SCE2. In this example, the difference in luminance between the light emitted from a first sub-middle layer SML1 and the light emitted from a second sub-middle layer SML2 can be finely controlled.

The first sub-middle layer SML1 may be disposed in a first sub-emission region SEA1 between the first pixel electrode PE1 and the first sub-common electrode SCE1.

The second sub-middle layer SML2 may be disposed in a second sub-emission region SEA2 between the first pixel electrode PE1 and the second sub-common electrode SCE2.

At least one of second, third, and fourth light-emitting elements ED2, ED3, and ED4 may have the same configuration as the first light-emitting element ED1 of FIG. 25. In this case, the first and second sub-common electrodes SCE1 and SCE2 of the first light-emitting element ED1 may be connected to first and second sub-common electrodes SCE1 and SCE2, respectively, of whichever of the second, third, and fourth light-emitting elements ED2, ED3, and ED4 has the same configuration as the first light-emitting element ED1.

The first sub-middle layer SML1 may have a 1-tandem structure that includes one red light-emitting layer, i.e., a first red light-emitting layer REML1, and the second sub-middle layer SML2 may have a 2-tandem structure that includes two red light-emitting layers, i.e., the first red light-emitting layer REML1 and a second red light-emitting layer REML2, which are disposed in first and second light-emitting units EU2_1 and EU2_2, respectively, with one charge generation layer, i.e., a charge generation layer CGL, interposed therebetween.

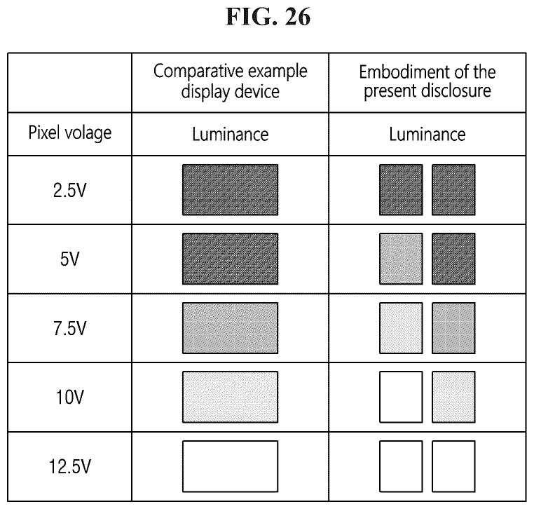

FIG. 26 is a table comparing the pixel voltage versus luminance of a display device according to one or more embodiments of the present disclosure with the pixel voltage versus luminance of a comparative example display device.

As already mentioned above, as the number of light-emitting layers included in a first sub-middle layer of a middle layer differs from the number of light-emitting layers included in a second sub-middle layer of the middle layer, the first and second sub-middle layers can emit light with different gray levels (or luminances) in accordance with the electric field between a pixel electrode and a common electrode. For example, the first and second sub-middle layers may provide light with different luminances in response to the voltage applied to the pixel electrode (e.g., a pixel voltage). For example, when a pixel voltage of 7.5V is applied to the pixel electrode, the first sub-middle layer, which has a relatively smaller number of light-emitting layers, may emit light (hereinafter, the first light) with a higher luminance, and the second sub-middle layer, which has a relatively larger number of light-emitting layers, may emit light (hereinafter, the second light) with a lower luminance than the first light. In other words, the first light emitted from the first sub-middle layer may have a higher luminance than the second light emitted from the second sub-middle layer.

When a pixel voltage of 2.5V or 5V is applied, the light-emitting element of the comparative example display device, is off, but the first sub-middle layer of the light-emitting element of the display device according to one or more embodiments of the present disclosure emits light.

The comparative example display device exhibits the same minimum gray level (e.g., a full-black gray level) for pixel voltages of 2.5V and 5V, but the display device according to one or more embodiments of the present disclosure can exhibit different gray levels for the pixel voltages of 2.5V and 5V. For example, the display device according to one or more embodiments of the present disclosure may display an image with a minimum gray level at a pixel voltage of 2.5 V and an image with a higher gray level at a pixel voltage of 5V. For example, the first and second sub-middle layers of the display device according to one or more embodiments of the present disclosure may display an image with a gray level higher than the minimum gray level and an image with the minimum gray level, respectively, at a pixel voltage of 5V. Consequently, the display device according to one or more embodiments of the present disclosure can present a broader range of gray levels in each pixel even at lower voltages. As a result, the usable range of pixel voltages can be expanded.

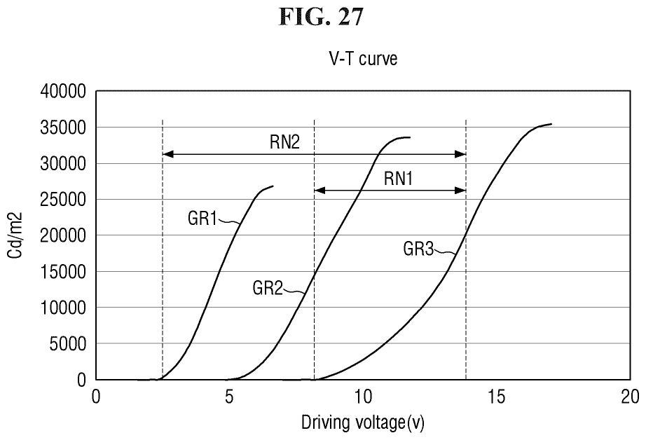

FIG. 27 is a graph illustrating the variation of light transmittance versus driving voltage for different tandem structures.

Referring to FIG. 27, the X axis represents driving voltage, and the Y axis represents luminance.

A first curve GR1 is a driving voltage-to-light transmittance curve for a 1-tandem structure that includes one light-emitting layer in one pixel, a second curve GR2 is a driving voltage-to-light transmittance curve for a 2-tandem structure that includes two light-emitting layers, which are stacked in a third direction DR3, in one pixel, and a third curve GR3 may be a driving voltage-to-light transmittance curve for a 3-tandem structure that includes three light-emitting layers, which are stacked in the third direction DR3, in one pixel.

Referring again to FIG. 26, the display device according to one or more embodiments of the present disclosure can emit light even at lower voltages. Consequently, as illustrated in FIG. 27, a usable volage range RN2 of the display device according to one or more embodiments of the present disclosure may be wider than a usable voltage range RN1 of the comparative example display device.

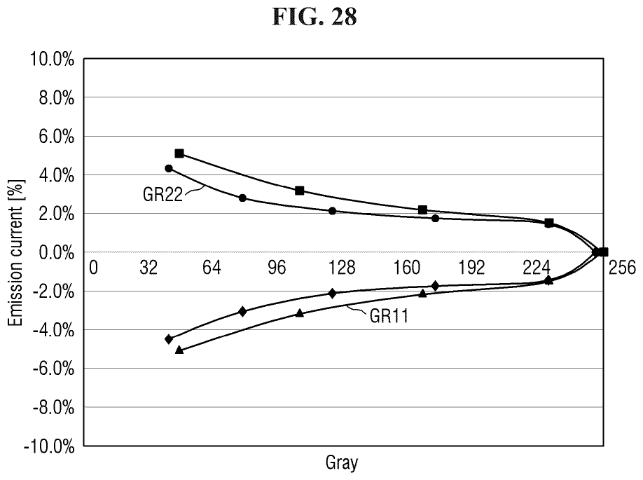

FIG. 28 is a graph comparing the error rate of the display device according to one or more embodiments of the present disclosure and the error rate of the comparative example display device.

Referring to FIG. 28, the X axis represents gray level, and the Y axis represents the error rate of a driving current.

A first curve GR11 represents the characteristic curve of the comparative example display device showing the error rate of a driving current (Ids) applied to a light-emitting element via a driving transistor (DT) when the threshold voltage (Vth) of the driving transistor is shifted in a positive or negative direction from its normal magnitude.

When the threshold volage of the driving transistor in the comparative example display device is shifted in the positive direction from its normal magnitude, the error rate of the driving current was observed to be greater than 5% in the high-gray-level range and greater than 2% in the low-gray-level range. Here, the shift deviation of the threshold voltage in the positive direction may be, for example, approximately +50 mV.

When the threshold voltage of the driving transistor in the comparative example display device is shifted in the negative direction from its normal magnitude, the error rate of the driving current was observed to be greater than 5% in the high-gray-level range and greater than 2% in the low-gray-level range. Here, the negative shift deviation of the threshold voltage can be, for example, approximately-50 mV.

A second curve GR22 represents the characteristic curve of the display device according to one or more embodiments of the present disclosure showing the error rate of a driving current (Ids) applied to a light-emitting element via a driving transistor (DT) when the threshold voltage (Vth) of the driving transistor is shifted in a positive or negative direction from its normal magnitude.

When the threshold volage of the driving transistor in the display device according to one or more embodiments of the present disclosure is shifted in the positive direction from its normal magnitude, the error rate of the driving current was observed to be less than 5% in the high-gray-level range and less than 2% in the low-gray-level range. Here, the shift deviation of the threshold voltage in the positive direction may be, for example, approximately +50 mV.

When the threshold voltage of the driving transistor in the display device according to one or more embodiments of the present disclosure is shifted in the negative direction from its normal magnitude, the error rate of the driving current was observed to be less than 5% in the high-gray-level range and less than 2% in the low-gray-level range. Here, the negative shift deviation of the threshold voltage can be, for example, approximately-50 mV.

The display device according to one or more embodiments of the present disclosure can lower the error rate of the driving current of the driving transistor. Accordingly, luminance deviations between pixels can be prevented, regardless of deviations in the threshold voltage between the pixels. This improvement ensures that the image quality of the display device according to one or more embodiments of the present disclosure can be improved.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
a substrate;
a first electrode on the substrate;
a second electrode on the first electrode; and
a first middle layer between the first electrode and the second electrode in a first emission region, wherein:
the first middle layer comprises a plurality of sub-middle layers in the first emission region; and
the sub-middle layers of the first middle layer have different thicknesses.

2. The display device of claim 1, wherein the sub-middle layers of the first middle layer comprise different numbers of light-emitting layers.

3. The display device of claim 1, wherein thicknesses of the sub-middle layers of the first middle layer are distances from a bottom surface of the first middle layer to top surfaces of uppermost light-emitting layers of the sub-middle layers of the first middle layer.

4. The display device of claim 3, wherein the bottom surface of the first middle layer is an interface between the first electrode and the first middle layer.

5. The display device of claim 3, wherein the uppermost light-emitting layers of the sub-middle layers of the first middle layer are most distant light-emitting layers of the sub-middle layers of the first middle layer from the first electrode.

6. The display device of claim 3, wherein the top surfaces of the uppermost light-emitting layers of the sub-middle layers of the first middle layer are interfaces between the uppermost light-emitting layers of the sub-middle layers of the first middle layer and uppermost electron transport layers of the sub-middle layers of the first middle layer.

7. The display device of claim 1, wherein the sub-middle layers of the first middle layer comprise different numbers of light-emitting units.

8. The display device of claim 7, wherein each of the sub-middle layers of the first middle layer further comprises a charge generation layer located between neighboring light-emitting units.

9. The display device of claim 7, wherein the first middle layer further comprises a functional layer in each of the light-emitting units.

10. The display device of claim 1, further comprising:
a third electrode between the substrate and the second electrode; and
a second middle layer between the second electrode and the third electrode in a second emission region, wherein:
the second middle layer comprises a plurality of sub-middle layers located in the second emission region; and
the sub-middle layers of the second middle layer have different thicknesses.

11. The display device of claim 10, wherein the sub-middle layers of the second middle layer have a same thickness as their corresponding sub-middle layers of the first middle layer.

12. The display device of claim 11, wherein the sub-middle layers of the second middle layer comprise a same number of light-emitting layers as their corresponding sub-middle layers of the first middle layer.

13. The display device of claim 10, wherein the sub-middle layers of the second middle layer have a different thickness from their corresponding sub-middle layers of the first middle layer.

14. The display device of claim 13, wherein the sub-middle layers of the second middle layer comprise a different number of light-emitting layers from their corresponding sub-middle layers of the first middle layer.

15. The display device of claim 1, wherein the second electrode comprises a plurality of sub-electrodes on the sub-middle layers of the first middle layer.

16. The display device of claim 15, wherein the sub-electrodes are separate from one another.

17. The display device of claim 1, wherein the first emission region comprises a plurality of sub-emission regions corresponding to the sub-middle layers of the first middle layer.

18. The display device of claim 1, further comprising:
a color filter on the second electrode in the first emission region.

19. The display device of claim 1, wherein the sub-middle layers of the first middle layer comprise light-emitting layers configured to emit a same color of light.

20. The display device of claim 1, wherein the sub-middle layers of the first middle layer comprise light-emitting layers configured to emit different colors of light.

21. The display device of claim 1, wherein the sub-middle layers of the first middle layer are arranged in one direction.

22. The display device of claim 1, wherein the sub-middle layers of the first middle layer comprise a first sub-middle layer and a second sub-middle layer having a greater thickness than the first sub-middle layer and surrounding the first sub-middle layer.

23. A display device comprising:
a substrate;
a first electrode on the substrate;
a second electrode on the first electrode; and
a middle layer between the first electrode and the second electrode in an emission region, wherein:
the middle layer comprises a plurality of sub-middle layers in the emission region; and
at least two of the sub-middle layers comprise different numbers of light-emitting layers.

24. The display device of claim 23, wherein the at least two of the sub-middle layers have different thicknesses.
